(19) United States
(12) Patent Application Publication
(10) Pub. No.: US 2012/0216865 A1
(43) Pub. Date: Aug. 30, 2012

(54) HETEROJUNCTION DEVICE

(75) Inventor: Henry J. Snaith, Abingdon (GB)

(73) Assignee: ISIS INNOVATION LIMITED, Summertown, Oxford (UK)

(21) Appl. No.: 13/395,405

(22) PCT Filed: Sep. 13, 2010
(86) PCT No.: PCT/GB2010/001728

§ 371 Date: May 21, 2012

(30) Foreign Application Priority Data
Sep. 11, 2009 (GB) 0916037.5

(51) Int. Cl. H01L 51/44; H01L 51/48; H01L 51/46

(52) U.S. Cl. 136/263; 257/40; 438/82; 257/E51.026; 257/E51.015

(57) ABSTRACT

A solid-state p-n heterojunction comprising an organic p-type material in contact with an n-type material wherein said n-type material is surface-sensitised by at least two sensitizing agents comprising an energy donor sensitizing agent and an energy acceptor sensitizing agent and optionally at least one intermediate sensitizing agent, wherein the emission spectrum of the donor sensitizing agent overlaps with the absorption spectrum of the acceptor sensitizing agent and/or at least one intermediate sensitizing agent where present, and the emission spectrum of at least one intermediate sensitizing agent where present overlaps with the absorption spectrum of the acceptor sensitizing agent and wherein the acceptor sensitizing agent individually has a maximum Absorbed Photon to electron Conversion Efficiency of no less than 40% in an equivalent heterojunction when used as sole sensitizing agent. The invention also provides optoelectronic devices such as solar cells or photo sensors comprising such a p-n heterojunction, and methods for the manufacture of such a heterojunction or device.

The present invention relates to a solid-state p-n heterojunction and to its use in optoelectronic devices, in particular in solid-state dye-sensitized solar cells (SDSCs) and corresponding light sensing devices.

The junction of an n-type semiconductor material (known as an electron transporter) with a p-type semiconductor material (known as a hole-transporter) is perhaps the most fundamental structure in modern electronics. This so-called “p-n heterojunction” forms the basis of most modern diodes, transistors and related devices including opto-electronic devices such as light emitting diodes (LEDs), photovoltaic cells, and electronic photo-sensors.

A realization of the pressing need to secure sustainable future energy supplies has led to a recent explosion of interest in photovoltaics (PV). Conventional semi-conductor based solar cells are reasonably efficient at converting solar to electrical energy. However, it is generally accepted that further major cost reductions are necessary to enable widespread uptake of solar electricity generation, especially on a larger scale. Dye-sensitized solar cells (DSCs) offer a promising solution to the need for low-cost, large-area photovoltaics. Typically, DSCs are composed of mesoporous TiO₂ (electron transporter) sensitized with a light-absorbing molecular dye, which in turn is contacted by a redox-active hole-transporting medium. Photo-excitation of the sensitizer leads to the transfer (injection) of electrons from the excited dye into the conduction band of the TiO₂. These photo-generated electrons are subsequently transported to and collected at the anode. The oxidized dye is regenerated via hole-transfer to the redox active medium with the holes being transported through this medium to the cathode.

The most efficient DSCs are composed of TiO₂ in combination with a redox active liquid electrolyte. Those incorporating an iodide/triiodide redox couple in a volatile solvent can convert over 12% of the solar energy into electrical energy. However, this efficiency is far from optimum. Even the most effective sensitizer/electrolyte combination which uses a ruthenium complex with an iodide/triiodide redox couple sacrifices approx. 600 mV in order to drive the dye regeneration/iodide oxidation reaction. Furthermore, such systems are optimised to operate with sensitizers which predominantly absorb in the visible region of the spectrum thereby losing out on significant photocurrent and energy conversion. Even in the most efficiently optimised liquid electrolyte-based DSCs, photons which are not absorbed between 600 and 800 nm amount to an equivalent of 7 mA/cm⁻² loss in photocurrent under full sun conditions. Other problems with the use of liquid electrolytes are that these are corrosive and often prone to leakage, factors which become particularly problematical for larger-scale installations or over longer time periods.

More recent work has focused on creating gel or solid-state electrolytes, or entirely replacing the electrolyte with a solid-state molecular hole-transporter which is much more appealing for large scale processing and durability. Of these alternatives, the use of a molecular hole-transporter appears to be the most promising. Though these solid-state DSCs (SDSCs) are a proven concept, the most efficient still only convert just over 5% of the solar energy into usable electrical power. This is still a long way off the efficiency of the liquid based cells and will require further optimisation before SDSCs can become a viable commercial prospect in routine applications.

The rates of many of the charge-transfer steps in a DSC-type optoelectronic device are highly dependent upon the environment in which the relevant materials are held. For example, although the “injection” step of transferring an excited electron from a sensitizer to the n-type material is essentially quantitative in electrolyte-based DSCs, in solid state devices this step is relatively slow and a significant proportion of electrons are quenched by other pathways before they can be transferred to the n-type material. As a result, many of the approaches used to improve the efficiency of electrolyte-type DSCs are not applicable in the solid state devices, especially those relating to electron injection and dye quenching.

Although thicker layers of n-type semiconductor allow for more surface for dye loading, losses at the semiconductor junction mean that thick layers of n-type material result in impaired efficiency. As a result, the more densely a dye can be loaded and the greater its extinction coefficient the better because this allows the thickness of the n-type material to be minimised. Thus, for highest efficiency, it is preferable for as much light as possible to be absorbed at the surfaces of an n-type material layer only a few μm deep. This absorbed light would then result in more excited electrons which could be transferred to the n-type material. However, those sensitizers which show the greatest potential for light harvesting over a broad spectrum are often poorly suited for transferring the electrons from their excited states to the n-type material. A balance must therefore be struck giving maximum energy conversion taking into account many conflicting factors.

One approach which has been investigated in solution solar cells is the use of two dyes having complimentary absorption spectra to improve light harvesting capacity. Although this can result in improved efficiency, there is still a considerable limitation on the dyes used since both must be capable of transferring electrons from the dye's excited state to the n-type semiconductor. These methods are not known to have been applied in the solid state, where injection of electrons into the n-type material can be more problematic.

The present inventors have now established that by appropriate choice of sensitizers, solid-state p-n heterojunctions can be generated having a high light gathering capacity over a broad spectrum with the need only that the sensitizer with the lowest energy excited state be capable of efficient electron injection in to the n-type material. This invention relies on establishing for the first time that efficient transfer of energy is possible between two or more surface-absorbed sensitizers in a solid state heterojunction such as a solid state solar cell.

In a first aspect, the present invention therefore provides a solid-state p-n heterojunction comprising an organic p-type material in contact with an n-type material wherein said n-type material is surface-sensitised by at least two sensitizing agents comprising a donor sensitizing agent and an acceptor sensitizing agent and optionally at least one intermediate sensitizing agent, wherein the emission spectrum of the donor sensitizing agent overlaps with the absorption spectrum of the acceptor sensitizing agent and/or with the absorption spectrum of at least one intermediate sensitizing agent where present, and the emission spectrum of at least one intermediate sensitizing agent where present overlaps with the absorption spectrum of the acceptor sensitizing agent; and wherein the acceptor sensitizing agent individually has a maximum Absorbed Photon-to-electron Conversion Efficiency (APCE) of no less than 40% in an equivalent heterojunction when used as sole sensitizing agent.

The junction will preferably comprise a solid p-type material (hole transporter) in the form of an organic semiconductor, such as a molecular, oligomeric or polymeric hole transporter. In one embodiment the p-type material is an optionally amorphous molecular organic compound.

The solid-state p-n heterojunctions of the present invention are particularly suitable for use in solar cells, photo-detectors and other optoelectronic devices. In a second aspect, the present invention therefore provides an optoelectronic device comprising at least one solid state p-n heterojunction of the invention, as described herein. All references to a heterojunction herein may be taken to refer equally to an optoelectronic device including referring to a solar cell or to a photo-detector where context allows.

In a corresponding further aspect, the present invention additionally provides the use of at least two sensitizing agents comprising a donor sensitizing agent and an acceptor sensitizing agent and optionally at least one intermediate sensitizing agent, wherein the emission spectrum of the donor sensitizing agent overlaps with the absorption spectrum of the acceptor sensitizing agent and/or with the absorption spectrum of at least one intermediate sensitizing agent where present, and the emission spectrum of at least one intermediate sensitizing agent where present overlaps with the absorption spectrum of the acceptor sensitizing agent; and wherein the acceptor sensitizing agent individually has a maximum Absorbed Photon to electron Conversion Efficiency of no less than 40% in an equivalent heterojunction when used as sole sensitizing agent; in a solid-state p-n heterojunction. This will preferably be a heterojunction of the present invention as described herein.

Thus the invention provides the use of at least two sensitizing agents comprising a donor sensitizing agent and an acceptor sensitizing agent and optionally at least one intermediate sensitizing agent all as described herein in a solid-state p-n heterojunction.

The use in all appropriate aspects of the invention will preferably be a use to generate increased charge transfer in the solid-state p-n heterojunction in comparison with any of the individual sensitizing agents used as sole sensitizer in an equivalent heterojunction. In particular, the use will preferably be to bring about such an increase at least partially by resonant energy transfer between the donor sensitizer and the acceptor sensitizer.

The use in all appropriate aspects of the invention will preferably be in an optoelectronic device such as any of those described herein.

In a still further aspect, the present invention provides a method for the manufacture of a solid-state p-n heterojunction comprising: forming a layer (optimally a porous layer) of an n-type semiconductor material and surface sensitizing said layer simultaneously or sequentially with at least two sensitizing agents comprising a donor sensitizing agent and an acceptor sensitizing agent and optionally at least one intermediate sensitizing agent, wherein the emission spectrum of the donor sensitizing agent overlaps with the absorption spectrum of the acceptor sensitizing agent and/or with the absorption spectrum of at least one intermediate sensitizing agent where present, and the emission spectrum of at least one intermediate sensitizing agent where present overlaps with the absorption spectrum of the acceptor sensitizing agent.

The surface sensitizing of the layer of n-type semiconductor material is preferably by surface absorption of the indicated sensitizing agents. It is preferable that the sensitizing agents are separate agents which may be absorbed by sequential contact of the surface with individual solutions of the desired sensitizing agents and/or by contact with solutions containing appropriate concentrations of at least two of the desired sensitizing agents.

The solid-state p-n heterojunction formed or formable by any of the methods described herein evidently constitutes a further aspect of the invention, as do optoelectronic devices such as photovoltaic cells or light sensing devices comprising at least one such heterojunction.

The functioning of a DSC relies initially on the collection of solar light energy in the form of capture of solar photons by a sensitizer (typically a molecular, metal complex, or polymer dye or “quantum dot”). The effect of the light absorption is to raise an electron into a higher energy level in the sensitizer. This excited electron will eventually decay back to its ground state, but in a DSC, the n-type material in close proximity to the sensitizer provides an alternative (faster) route for the electron to leave its excited state, viz. by “injection” into the n-type semiconductor material. This injection results in a charge separation, whereby the n-type semiconductor has gained a net negative charge and the dye a net positive. Since the dye is now charged, it cannot function to absorb a further photon until it is “regenerated” and this occurs by passing the positive charge (“hole”) on to the p-type semiconductor material of the junction (the “hole transporter”). In a solid state device, this hole transporter is in direct contact with the dye material, while in the more common electrolytic dye sensitised photocells, a redox couple (typically iodide/triiodide) serves to regenerate the dye and transports the “hole species” (triiodide) to the counter electrode. Once the electron is passed into the n-type material, it must then be transported away, with its charge contributing to the current generated by the solar cell.

While the above is a simplified summary of the ideal working of a DSC, there are certain processes which occur in any practical device in competition with these desired steps and which serve to decrease the conversion of sunlight into useful electrical energy. Decay of the sensitizer back to its ground state was indicated above, and the efficiency of the conversion of absorbed photons into current will depend upon the relative speeds of the injection process and competing processes such as quenching or decay. Issues such as the matching of the excited state in the dye to the conduction band of the n-type material are of importance in this balance, and some dyes having high light absorption efficiencies at relatively low wavelengths are not effective in this transfer, at least partially because of this less efficient matching. Furthermore, larger π-conjugated dyes which exhibit very high molar extinction coefficients, often undergo aggregation which also reduces the electron transfer efficiency. ¹{Wenger, et al. J. AM. CHEM. SOC. 2005, 127, 12150-12151}.

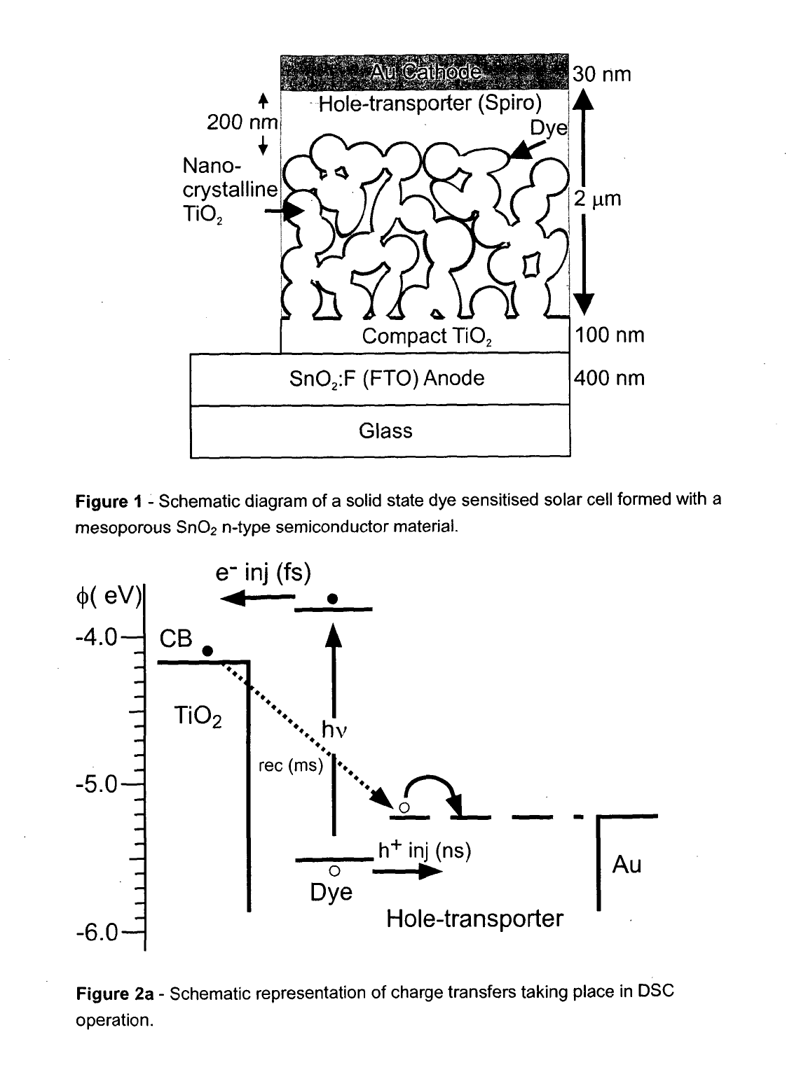

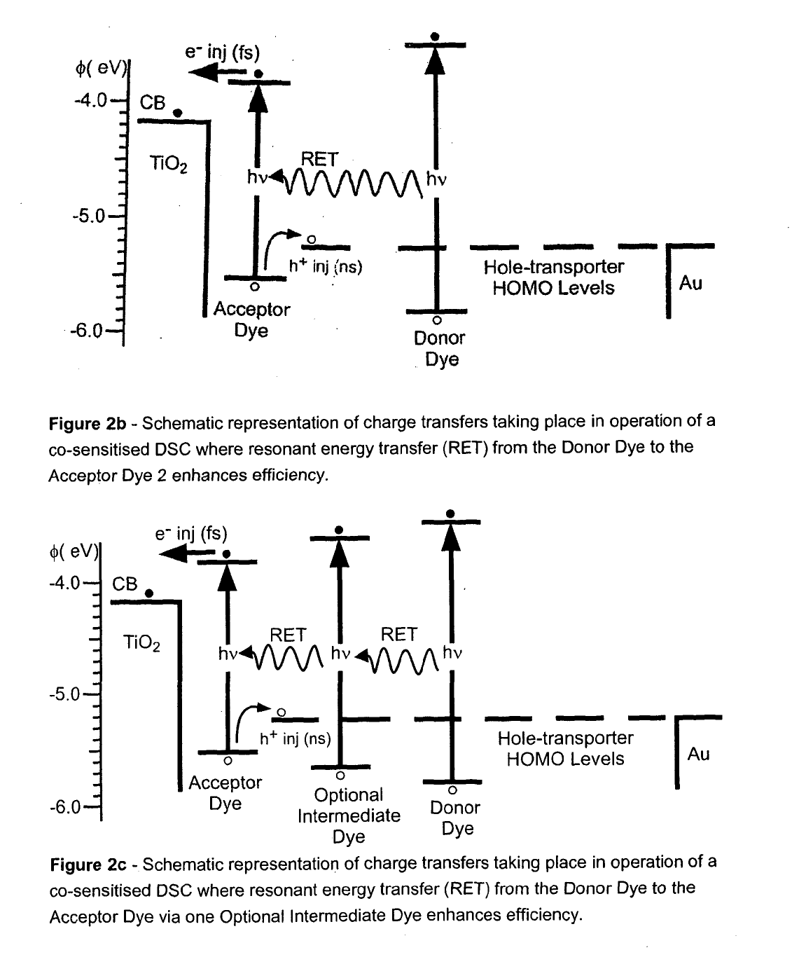

A schematic diagram indicating a typical structure of the solid-state DSC is given in attached FIG. 1 and a diagram indicating some of the key steps in electrical power generation from a DSC is given in attached FIG. 2a. FIGS. 2b and 2c show simplified energy transfer steps in embodiments of the present invention.

Through the present invention, the inventors have now established that a range of dyes with complimentary absorption characteristics may be used even if those one or more dyes absorbing at shorter wavelength have low efficiency in direct transfer of excited electrons to the n-type semiconductor. This is because the close proximity of the dyes absorbed onto the surface of the n-type semiconductor layer allows for resonant energy transfer (RET) between one dye and another of longer absorption wavelength.

Dyes having an absorption maximum at short wavelength and/or having a high energy excited state are referred to herein alternatively as “high energy dyes” while those having an absorption maximum at long wavelength and/or having a low energy excited state are referred to herein as “low energy dyes”. The terms higher and lower energy take the corresponding meaning. In the systems described herein, the “donor” sensitizer will be the dye of highest energy and the “acceptor” will have a lower energy and will typically be of lowest energy dye used. Where one or more intermediate sensitizers are used, these will be of intermediate energy between the donor and the acceptor. The terms “dye” and “sensitizer” are used equivalently to include not only conventional dyes but also “quantum dot” type senstizers as are well known and also described herein.

It is preferable that the donor sensitizing agent will have a maximum extinction coefficient of at least 5,000 (e.g. 10 000 to 500,000) M⁻¹ cm⁻¹, preferably at least 13,000 M⁻¹ cm⁻¹ and more preferably at least 50,000 M⁻¹ cm⁻². It is also preferable that the donor sensitizing agent will have a high extinction coefficient (e.g. at least 50% of its maximum, preferably at least 75% of its maximum) over a spectral bandwidth of at least 200 nm, preferably at least 300 nm and more preferably at least 350 nm. For donor sensitizers, the region of high extinction coefficient should preferably be in the UV to IR regions of the electromagnetic spectrum, preferably in the UV to visible regions. Suitable regions in which the dyes will preferably have high extinction coefficients may be between 200 nm and 1000 nm, preferably between 300 nm and 800 nm, and more preferably between 350 nm and 750 nm. The width of the high extinction coefficient region (e.g. as defined above) may be the whole of these regions or may be a band of spectral bandwidth as defined above within these regions.

The present invention takes advantage of RET by providing an “acceptor” sensitizer with high absorption wavelength and high injection efficiency which acts as a “sink” for the photoexcitation energy. All other sensitizers will have at least one path by which RET can lead a electronic excitation energy to the acceptor sensitizer. Many dyes will also provide a certain degree of direct injection, but this is made unimportant by the use of RET and in one embodiment may be of low efficiency. The RET “path” leading from any other dye to the acceptor sensitizer may be direct, where the emission spectrum of the dye in question overlaps with the absorption spectrum of the acceptor. Alternatively, there may be a “cascade” of transfers by which an electron excitation steps down from one dye to another of lower energy, finishing eventually either injected into the n-type material or at the acceptor sensitizer, which then subsequently injects the electron into the n-type material.

It is preferable that the acceptor sensitizing agent will have a maximum extinction coefficient of at least 5,000 (e.g. 5 000 to 500,000) M⁻¹ cm⁻¹, preferably at least 13,000 M⁻¹ cm⁻² and more preferably at least 100,000 (e.g. at least 200,000) M⁻¹ cm⁻² It is also preferable that the acceptor sensitizing agent will have a high extinction coefficient (e.g. at least 50% of its maximum, preferably at least 75% of its maximum) over a spectral bandwidth of at least 50 nm, preferably at least 100 nm and more preferably at least 200 nm. For acceptor sensitizers, the region of high extinction coefficient should preferably be in the visible to IR regions of the electromagnetic spectrum. Suitable regions in which the dyes will preferably have high extinction coefficients may be between 400 nm and 2000 nm, preferably between 500 nm and 1000 nm, and more preferably between 550 nm and 900 nm. The width of the high extinction coefficient region (e.g. as defined above) may be the whole of these regions or may be a band of spectral bandwidth as defined above within these regions.

In view of the above, it corresponds that the donor sensitizer must have an emission spectrum overlapping with the absorption spectrum of at least one other sensitizer in the system (i.e. forming the p-n-heterojunction). In addition, the acceptor must have an absorption spectrum overlapping with the emission spectrum of at least one other dye (of higher energy) in the system (i.e. forming the p-n-heterojunction). Intermediate sensitizers must allow downward transmission of energy by overlap of their emission spectrum with the absorption spectrum of a sensitizer of lower energy and if they are forming part of a cascade then they will also have suitable absorption spectrum overlap with the emission spectrum of a dye of higher energy to allow the excited state energy to be passed from a dye of higher energy.

In all of the aspects of the invention, the peak absorption wavelength of the donor sensitizing agent will preferably be shorter than that of any intermediate sensitizing agents and the peak absorption wavelength of the acceptor sensitizing agent will preferably be longer than that of any intermediate sensitizing agents. Needless to shy, the peak absorption wavelength of the donor sensitizing agent will preferably be shorter than that of the acceptor sensitizing agent.

It is evident from the above that the donor and/or the intermediate (if present) sensitizing agents need not have a high degree of direct electron transfer efficiency. This is a very significant advantage because the pressure of requiring efficient charge transfer to the semiconductor puts significant design constraints on the dyes which can be used for “direct” sensitization (i.e. sensitization where the dye both absorbs the light and transfers the resulting excited-state electron to the conduction band of the semiconductor). The invention allows the separation of these processes such that the donor dye may be made efficient at light absorption without constraint regarding charge transfer and/or the acceptor may be made an efficient injector without worrying that it has low absorption efficiency or narrow absorption bandwidth (providing of course that effective RET can be established). By optimising these criteria separately, the overall efficiency of the device may therefore be improved.

In one embodiment, therefore, it is preferred the donor sensitizing agent has a maximum Absorbed Photon to electron Conversion Efficiency of less than 50% (e.g. 0.01 to 50%) in an equivalent heterojunction when used as sole sensitizing agent. This efficiency may be as low as less than 40%, preferably less than 20% and more preferably less than 10%. Those with less than 5% or even less than 1% Absorbed Photon-to-electron Conversion Efficiency may also be used.

Correspondingly, it is indicated herein in the various aspects of the invention that the acceptor sensitizing agent should have a high Absorbed Photon to electron Conversion Efficiency (APCE—referred to also herein and in the art as efficient electron injection or efficient conversion). It is preferable that the acceptor sensitizer has an APCE of at least 40% (preferably at least 50%) in equivalent cells when used as the sole sensitizer. This may be, for example 40 to 99.9% or 50 to 99.9% and is preferably at least 60%, more preferably at least 75% and most preferably at least 80%. It is important to appreciate that in electrolyte-containing DSCs, this efficiency is typically very high for many sensitizers. In solid state heterojunctions, such as those which are the subject of the present invention, however, the solid-state nature typically renders this conversion efficiency much lower. Thus, it is a much more routine task to develop electrolytic DSCs utilising more than one dye because most of the available known sensitizers can be expected to have realistic conversion efficiencies. In solid state DSCs, (SDSCs), however, no co-sensitization is known to have been attempted, perhaps due to the expected limitations on usable dyes due to the need for efficient electron injection.

As used herein the terms “donor” and “acceptor” in the context of dyes and/or sensitizers relate to the property of donating or accepting energy. Thus, a donor sensitizer is used ton indicate an energy donor sensitizer and an acceptor sensitizer is used to indicate an energy acceptor sensitizer. Correspondingly, a sensitizer such as an intermediate sensitizer which may be both a donor and an acceptor will be a donor and acceptor of energy. This transferred energy will typically be in the form of electronic excitation energy.

Methods for assessing APCE are well known in the art, and depend upon measurement of the current generated for a particular light intensity and wavelength, combined with a measurement or estimate of the fraction of light absorbed in the device as a function of incident light energy (wavelength). The former step is easily accomplished with standard equipment while the latter step is either carried out through optical modelling or through direct measurements on the solar cell by measuring the reflectance and transmission spectra in an integrating sphere. It is preferred to use the latter, experimental method and all references to APCE in the description and examples of the present invention refer to this method where context allows. References for optical modeling for APCE (also known and Internal Quantum Efficiency (IQE):

Matt Law et al. described reflectance measurements and optical modelling in teh context of APCE in J. Nozik Nano Lett., 2008, 8, pp 3904-3910. Optical Modeling methods were described in Appl. Phys. B 86, 721-727 (2007). These are hereby incorporated by reference and supplement the above method, which is described in further detail in the attached examples.

There are two primary embodiments of the present invention; that in which the at least one intermediate sensitizing agent is absent, and that in which the intermediate dye is present. In the first of these embodiments, all aspects of the invention relate to devices, methods uses etc of and in a solid-state p-n heterojunction comprising an organic p-type material in contact with an n-type material wherein said n-type material is surface-sensitized by two sensitizing agents comprising (and preferably consisting of) a donor sensitizing agent and an acceptor sensitizing agent, wherein the emission spectrum of the donor sensitizing agent overlaps with the absorption spectrum of the acceptor sensitizing agent and wherein the acceptor sensitizing agent individually has a maximum Absorbed Photon-to-electron Conversion Efficiency of no less than 40% in an equivalent heterojunction when used as sole sensitizing agent. All preferred aspects and embodiments of the invention apply to this embodiment to the extent that they are compatible.

The second principal embodiment is where at least one intermediate sensitizing agent is present. In this embodiment, the donor sensitizer may have an emission spectrum overlapping with at least one of the absorption spectra of the intermediate sensitizing agents, or directly with that of the acceptor sensitizing agent, or both. In this embodiment, all aspects of the invention relate to devices, methods uses etc of and in a solid-state p-n heterojunction comprising an organic p-type material in contact with an n-type material wherein said n-type material is surface-sensitised by at least three sensitizing agents comprising a donor sensitizing agent, an acceptor sensitizing agent and at least one intermediate sensitizing agent, wherein the emission spectrum of the donor sensitizing agent overlaps with the absorption spectrum of the acceptor sensitizing agent and/or with the absorption spectrum of at least one intermediate sensitizing agent, and the emission spectrum of at least one intermediate sensitizing agent overlaps with the absorption spectrum of the acceptor sensitizing agent and wherein the acceptor sensitizing agent individually has a maximum Absorbed Photon-to-electron Conversion Efficiency of no less than 40% in an equivalent heterojunction when used as sole sensitizing agent.

Some examples of dyes currently used in sensitizing DSCs are indicated below, but due to the nature of the invention, many dyes not having a useful direct electron conversion efficiency will be usable as donor or intermediate sensitizing agents. Many of these dyes will be well known and commonly available to those skilled in the art. The following dyes are generally those with a fair degree of electron conversion efficiency in electrolytic DSCs and may be suitable as donor, intermediate and/or acceptor sensitizers in appropriate embodiments of the invention. At least two dyes are required in the present invention and these will be different, although they may be of the same dye category. More preferably, the donor and acceptor sensitizers will be of different categories, such as from any two of those indicated below. In one embodiment at least one of the sensitizers is a quantum dot sensitizer. This may be the donor, acceptor and/or at least one intermediate sensitizer in any combination and the invention may be practiced with any combination of quantum dot sensitizers and metal—complex, molecular and/or polymeric dyes.

The most commonly used light sensitising materials in electrolytic DSCs are organic or metal-complexed dyes. These have been widely reported in the art and the skilled worker will be aware of many existing sensitizers, all of which are suitable in all appropriate aspects of the invention and consequently are reviewed here only briefly.

A common category of organic dye sensitizers are indolene based dyes, of which D102 D131 and D149 (shown below) are demonstrated in the attached Examples.

The general structure of indolene dyes is that of Formula sI below:

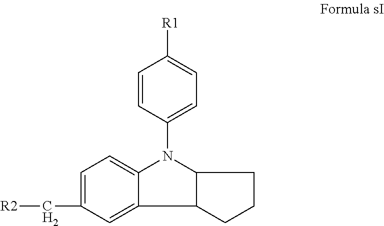

wherein R1 and R2 are independently optionally substituted alkyl, alkenyl, alkoxy, heterocyclic and/or aromatic groups, preferably with molecular weight less than around 360 amu. Most preferably, R1 will comprise aralkyl, alkoxy, alkoxy aryl and/or aralkenyl groups (especially groups of formula CₓH_{y}O_{z} where x, y and z are each 0 or a positive integer, x+z is between 1 and 16 and y is between 1 and 2x+1) including any of those indicated below for R1, and R2 will comprise optionally substituted carbocyclic, heterocyclic (especially S and/or N-containing heterocyclic)cycloalkyl, cycloalkenyl and/or aromatic groups, particularly those including a carboxylic acid group. All of the groups indicated below. for R2 are highly suitable examples. One preferred embodiment of R2 adheres to the formula CₓH_{y}O_{z}NᵥS_{w} where x, y, z, v and w are each 0 or a positive integer, x+z+w+v is between 1 and 22 and y is between 1 and 2x+v+1. Most preferably, z≧2 and in particular, it is preferable that R2 comprises a carboxylic acid group. These R1 and R2 groups and especially those indicated below may be used in any combination, but highly preferred combinations include those indicated below:

| Dye Name | R1 | R₂ |
|---|---|---|
| D₁₄₉ | Ph₂C═CH | 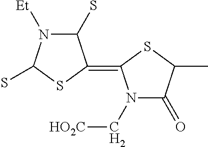 |
| D₁₀₂ | Ph₂C═CH | 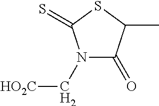 |
| D₇₇ | OMe | 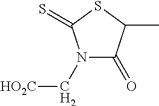 |
| D₁₀₃ | 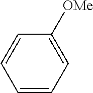 | 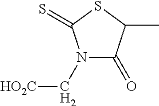 |
| D₁₃₁ | Ph₂C═CH | 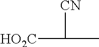 |
| D₁₂₀ | OMe | 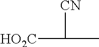 |

Indolene dyes are discussed, for example, in Horiuchi et al. J. Am. Chem. Soc. 126 12218-12219 (2004), which is hereby incorporated by reference.

A further common category of sensitizers are ruthenium metal-complexes, particularly those having two bipyridyl coordinating moieties. These are typically of formula sII below

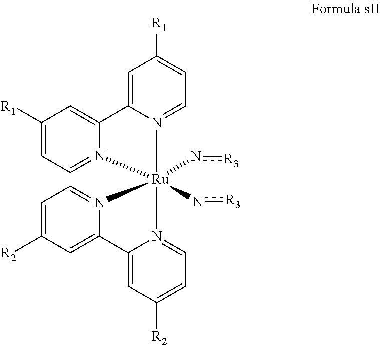

wherein each R1 group is independently a straight or branched chain alkyl or oligo alkoxy chain such as CₙH₂ₙ₊₁ where n is 1 to 20, preferably 5 to 15, most preferably 9, 10 or 11, or such as C—(—XCₙH₂ₙ—)ₘ—XCₚH₂ₚ₊₁, where n is 1, 2, 3 or 4, preferably 2, m is 0 to 10, preferably 2, 3 or 4, p is an integer from 1 to 15, preferably 1 to 10, most preferably 1 or 7, and each X is independently O, S or NH, preferably O; and wherein each R2 group is independently a carboxylic acid or alkyl carboxylic acid, or the salt of any such acid (e.g. the sodium, potassium salt etc) such as a CₙH₂ₙCOOY group, where n is 0, 1, 2 or 3, preferably 0 and Y is H or a suitable metal such as Na, K, or Li, preferably Na; and wherein each R3 group is single or double bonded to the attached N (preferably double bonded) and is of formula CHa—Z or C≡Z, where a is 0, 1 or 2 as appropriate, Z is a hetero atom or group such as S, O, SH or OH, or is an alkyl group (e.g. methylene, ethylene etc) bonded to any such a hetero atom or group as appropriate; R3 is preferably ═C═S.

A preferred ruthenium sensitizer is of the above formula sII, wherein each R1 is nonyl, each R2 is a carboxylic acid or sodium salt thereof and each R3 is double-bonded to the attached N and of formula ═C═S. R1 moieties of formula sII may also be of formula sIII below:

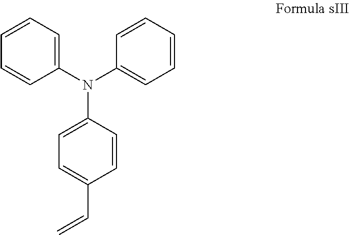

Ruthenium dyes are discussed in many published documents including, for example, Kuang et al. Nano Letters 6 769-773 (2006), Snaith et al. Angew. Chem. Int. Ed. 44 6413-6417 (2005), Wang et al. Nature Materials 2, 402-498 (2003), Kuang et al. Inorganica Chemica Acta 361 699-706 (2008), and Snaith et al. J Phys, Chem. Lett. 112 7562-7566 (2008), the disclosures of which are hereby incorporated herein by reference, as are the disclosures of all material cited herein.

Other sensitizers which will be known to those of skill in the art include Metal-Phalocianine complexes such as zinc phalocianine PCH001, the synthesis and structure of which is described by Reddy et al. (Angew. Chem. Int. Ed. 46 373-376 (2007)), the complete disclosure of which (particularly with reference to Scheme 1), is hereby incorporated by reference,

Some typical examples of metal phthalocianine dyes suitable for use in the present invention include those having a structure as shown in formula sIV below:

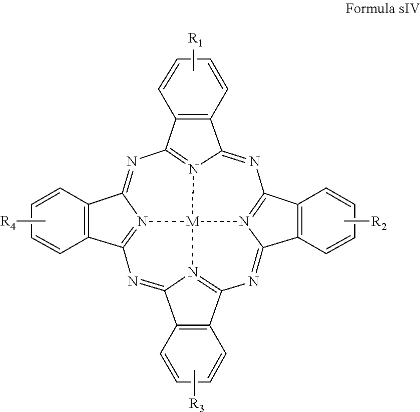

Wherein M is a metal ion, such as a transition metal ion, and may be an ion of Co, Fe, Ru, Zn or a mixture thereof. Zinc ions are preferred. Each of R1 to R4, which may be the same or different is preferably straight or branched chain alkyl, alkoxy, carboxylic acid or ester groups such as CₙH_{2n°1} where n is 1 to 15, preferably 2 to 10, most preferably 3, 4 or 5, with butyl, such as tertiary butyl, groups being particularly preferred, or such as OX or CO₂X wherein X is H or a straight or branched chain alkyl group of those just described. In one preferred option, each of R1 to R3 is an alkyl group as described and R4 is a carboxylic acid CO₂H or ester CO₂X, where X is for example methyl, ethyl, iso- or n-propyl or tert-, iso-, sec- or n-butyl. For example, dye TT1 takes the structure of formula sIV, wherein R1 to R3 are t-butyl and R4 is CO₂H.

Further examples of suitable categories of dyes include Metal-Porphyrin complexes, Squaraine dyes, Thiophene based dyes, fluorine based dyes, molecular dyes and polymer dyes. Examples of Squaraine dyes may be found, for example in Burke et al., Chem. Commun. 2007, 234, and examples of polyfluorene and polythiothene polymers in McNeill et al., Appl. Phys. Lett. 2007, 90, both of which are incorporated herein by reference. Metal porphyrin complexes include, for example, those of formula sV and related structures, where each of M and R1 to R4 can be any appropriate group, such as those specified above for the related phthalocyanine dyes:

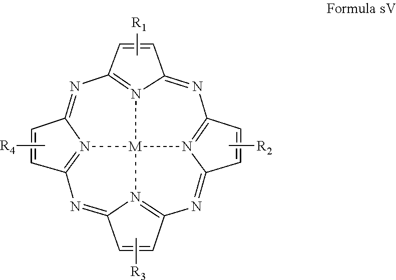

Squaraine dyes form a preferred category of dye for use in the present invention as donor, acceptor or any intermediate sensitizer where present. Squaraine dyes are particularly useful as acceptor sensitizers. They are also highly useful as one or more of any optionally included intermediate sensitizers. The above Burke citation provides information on Squaraine dyes, but briefly, these may be, for example, of the following formula sVI

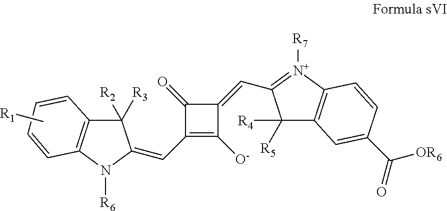

Wherein any of R1 to R8 may independently be a straight or branched chain alkyl group or any of R1 to R5 may independently be a straight or branched chain alkyloxy group such as CₙH₂ₙ₊₁ or CₙH₂ₙ₊₁O respectively where n is 1 to 20, preferably 1 to 12, more preferably 1 to 9. Preferably each R1 to R5 will be H, CₙH₂ₙ₊₁ or CₙH₂ₙ₊₁O wherein n is 1 to 8 preferably 1 to 3 more preferably 1 or two. Most preferably R1 is H and each R5 is methyl. Preferably each R6 to R8 group is H or CₙH₂ₙ₊₁ wherein n is 1 to 20, such as 1 to 12. For R6, n with preferably be 1 to 5 more preferably 1 to 3 and most preferably ethyl. For R7 n will preferably be 4 to 12, more preferably 6 to 10, most preferably 8, and for R8, preferred groups are H, methyl or ethyl. preferably H. One preferred squaraine dye referred to herein is SQ02, which is of formula sVI wherein R1 and R8 are H, each of R2 to R5 is methyl, R6 is ethyl, and R7 is octyl (e.g. n-octyl).

A further example category of valuable sensitizers are polythiophene (e.g. dithiophene)-based dyes, which may take the structure indicated below as formula sVII

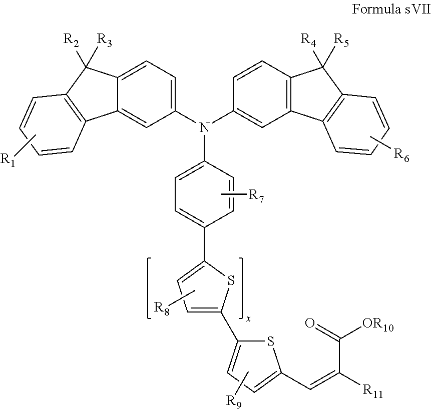

Wherein x is an integer between 0 and 10, preferably 1, 2, 3, 4 or 5, more preferably 1, and wherein any of R1 to R10 may independently be hydrogen, a straight or branched chain alkyl group or any of R1 to R9 may independently be a straight or branched chain alkyloxy group such as CₙH₂ₙ₊₁ or CₙH₂ₙ₊₁O respectively where n is 1 to 20, preferably 1 to 12, more preferably 1 to 5. It is preferred that each if R1 to R10 will independently be a hydrogen or CₙH₂ₙ₊₁ group where n is 1 to 5, preferably methyl, ethyl, n- or iso-propyl or n-, iso-, sec- or t-butyl. Most preferably, each of R2 to R4 will be methyl or ethyl and each of R1 and R6 to R10 will be hydrogen. The group R11 may be any small organic group (e.g. molecular weight less than 100) but will preferably be unsaturated and may be conjugated to the extended pi-system of the dithiophene groups. Preferred R11 groups include alkenyl or alkynyl groups (such as CₙH_{2n-1 and} CₙH₂ₙ₋₃ groups respectively, e.g. where n is 2 to 10, preferably 2 to 7), cyclic, including aromatic groups, such as substituted or unsubstituted phenyl, piridyl, pyrimidyl), pyrrolyl or imidazyl groups, and unsaturated hetero-groups such as oxo, nitrile and cyano groups. A most preferred R11 group is cyano. One preferred dithiophene based dye is 2-cyanoacrylic acid-4-(bis-dimethylfluorene aniline)dithiophene, known as JK2.

A further type of sensitizer which is highly appropriate for use in all aspects of the present invention is the so-called “quantum dot”. As indicated, these may be used as any or all of the sensitizers indicated for use in the present invention, alone or with molecular or polymeric sensitizers in any functional combination. Quantum dots (also known as “nano-dots” or “Q-dots”) are semiconductor particles of nanometer size wherein a gradual transition from bulk solid state to molecular structure occurs as the particles size decreases. The quantum dots are adsorbed at the heterojunction constituted by the n-type semiconductor (optionally coated as indicated herein) and the p-type semiconductor. As quantum dots, particles consisting of CdS, Bi₂S₃, Sb₂S₃ or Ag₂S may be used, whereas PbS is preferred. Other compounds suitable for making quantum-dots are InAs, CdTe, CdSe, HgTe. Solid solutions of HgTe and CdTe or of HgSe and CdSe are also suitable.

In the present invention, quantum dot sensitizers function exactly as molecular or polymeric dye sensitizers, whereby light is adsorbed by the Q-dots and produces electron-hole pairs. The electrons are injected from the Q-dots into the electron conducting solid (n-type material) while the holes are injected in the hole conducting side of the junction (p-type material). In this way electric power is produced from light. Quantum dot sensitized heterojunction cells offer several advantages. The band gaps and thereby the absorption ranges are adjustable through the particle size or by adjusting the relative concentrations of components in solid solutions like HgTe/CdTe or HgSe/CdSe. The band gap of these solutions may be adjusted to approach the optimal value for conversion of sunlight to electric power, which is about 1.3 eV for single junction and 0.9 eV as the IR absorbing cell in a tandem junction cell.

Another advantage is that the optical cross section of the Q-dots is significantly larger than that of the molecular dyes. This allows the use of thinner films resulting in higher photovoltages as well as better fill factors of the cell, and hence higher conversion yields. In one embodiment, the n-type material of the junctions and devices of the present invention may be planar or substantially planar rather than porous. Sensitisation wherein at least one of the sensitizers consists of Q-dots as described herein is particularly suitable for such planar, substantially planar or low porosity n-type materials (e.g. as described below). The production of a TiO₂-based SDSC sensitized with quantum dots is described in EP 1176646, the content of which is hereby incorporated by reference.

In one embodiment of the invention, where two sensitizers are used and where the n-type material is SnO₂ having at least one surface-coating of a high band gap or high band gap edge material (see below), the sensitizers will preferably not be the following parings: 1) a near-infra red absorbing zinc phalocianine dye in combination with an indoline or ruthenium-based sensitizers to absorb the bulk of the visible radiation; or 2) a polymeric or molecular visible light absorbing material used in conjunction with a near IR absorbing dye. This may be a visible light absorbing polyfluorene polymer used with a near IR absorbing zinc phlaocianine or squaraine dye.

In a related embodiment, the n-type material may be one that does not comprise SnO₂ having at least one surface-coating of a surface coating material having a conduction band edge closer to vacuum level and/or a higher band-gap than SnO₂. Such band gaps include those indicated herein.

Preferred combinations of dyes for use in the present invention (optionally where the n-type material is not SnO₂ having at least one surface-coating of a semiconductor material as described) include those indicated in the following tables, wherein the first table relates to combinations of two (donor and acceptor) sensitizers and the second table relates to combinations of three (donor, intermediate and acceptor) sensitizers:

TABLE S1
Combinations of two sensitizers.

| 2-Dye | | |
|---|---|---|
| Combi- | | |
| nation | Donor | Acceptor |
| 2a) | Indoline Dye | Metal-phthalocyanine dye |
| 2b) | Indoline Dye | Squaraine dye (SQ02) |
| 2c) | Indolene Dye | Metal-porphyrin sensitizer |
| 2d) | Indolene Dye | PbS nanoparticles |
| 2e) | Indolene Dye | PbSe nanoparticles |
| 2f) | Metal - ruthenium complex dye | Metal-phthalocyanine dye |
| 2g) | Metal - ruthenium complex dye | Squaraine dye |
| 2h) | Metal - ruthenium complex dye | Metal-porphyrin sensitizer |
| 2i) | Metal - ruthenium complex dye | PbS nanoparticles |
| 2j) | Metal - ruthenium complex dye | PbSe nanoparticles |
| 2k) | Metal-porphyrin complex sensitizer | Metal-phthalocyanine dye |
| 2l) | Metal-porphyrin complex sensitizer | Squaraine dye |
| 2m) | Metal-porphyrin complex sensitizer | PbS nanoparticles |
| 2n) | Metal-porphyrin complex sensitizer | PbSe nanoparticles |
| 2o) | Polyfluorene polymer dye | Metal-phthalocyanine dye |
| 2p) | Polyfluorene polymer dye | Squaraine dye |
| 2q) | Polyfluorene polymer dye | Metal-porphyrin sensitizer |
| 2r) | Polyfluorene polymer dye | PbS nanoparticles |
| 2s) | Polyfluorene polymer dye | PbSe nanoparticles |
| 2t) | Polythiophene polymer | Metal-phthalocyanine dye |
| 2u) | Polythiophene polymer | Squaraine dye |
| 2v) | Polythiophene polymer | Metal-porphyrin sensitizer |
| 2w) | Polythiophene polymer | PbS nanoparticles |
| 2x) | Polythiophene polymer | PbSe nanoparticles |

TABLE S2
Combinations of 3 sensitizers.

| 3-Dye | | | |
|---|---|---|---|
| Combi- | | | |
| nation | Donor | Intermediate | Acceptor |
| 3a) | D131 | D102 | TT1 |
| 3b) | Indolene | Indolene | Indolene |
| 3c) | Indolene | Indolene | Metal-phthalocyanine |
| 3d) | Indolene | Indolene | Squaraine dye |
| 3e) | Indolene | Indolene | Metal-Porphyrin |
| 3f) | Indolene | Indolene | PbS/PbSe |
| 3g) | Indolene | Ru-complex | PbS/PbSe |
| 3h) | Indolene | Metal-Porphyrin | PbS/PbSe |
| 3i) | Indolene | Squaraine | Metal-phthalocyanine |
| 3j) | Indolene | Metal-phthalocyanine | PbS/PbSe |
| 3k) | Indolene | Squaraine | PbS/PbSe |
| 3l) | Ru-Complex | Metal-phthalocyanine | PbS/PbSe |
| 3m) | Ru-Complex | Squaraine | PbS/PbSe |
| 3n) | Metal-Porphyrin | Squaraine | PbS/PbSe |

In the above Table S2, the intermediate sensitizer will act as a second donor, passing at least a portion of its excitation energy to the acceptor sensitizer. It is preferable that the intermediate also acts as an acceptor in accepting at least a portion of the excitation energy from the donor sensitizer, of which, in turn, at least a portion is then transferred on to the acceptor sensitizer. This applies both to the specific combinations noted above and to all aspects of the invention in which at least one intermediate sensitizer is present. That is to say, for all aspects and embodiments, it is necessary that intermediate sensitizers act as donors passing excitation energy to at least one dye of lower energy (the acceptor or a lower energy intermediate sensitizer) and it is preferable that intermediate sensitizer acts as an acceptor, accepting excitation energy from at least one sensitizer of higher energy, such as the donor or an intermediate sensitizer of higher energy.

Combinations of particular dyes which are particularly favoured for use in the present invention include at least one of D102, D149 and/or D131 with at least one of TT1 and/or SQ02. Specific combinations include:

| Combination | Donor | Acceptor |
|---|---|---|
| a) | D102 | TT1 |
| b) | D102 | SQ02 |
| c) | D149 | TT1 |
| d) | D131 | TT1 |
| e) | D149 | SQ02 |
| f) | D131 | SQ02 |
| g) | JK2 | TT1 |
| h) | JK2 | SQ02 |

(all dye abbreviations used are well known in the art and refer to the corresponding dyes described above).

In all aspects of the present invention a solid state hole transporter is a key constituent, since this forms the p-type material of the p-n heterojunction. The hole transporter will preferably be a molecular p-type material rather than an inorganic material such as a salt, and more preferably will be an organic molecular material. Suitable materials will typically comprise an extended pi-bonding system through which charge may readily pass. Suitable materials will also preferably be amorphous or substantially amorphous solids rather than being crystalline at the appropriate working temperatures (e.g. around 30-70° C.). The organic hole-transporter would preferably have a high energy HOMO to LUMO transition, rendering its predominant function dye-regeneration and hole-transport. However, it may optionally have a narrow HOMO to LUMO transition, with its additional function being to absorb solar light, and subsequently transfer an electron to the n-type material, or its excited state energy to a dye molecule tethered to the n-type material surface. The then excited dye molecule would subsequently transfer an electron to the n-type material and the hole to the hole-transporter, as part of the photovoltaic conversion process.

According to a preferred embodiment, the solid state hole transporter is a material comprising a structure according to any of formulae (tI), (tII), (tIII), (tIV) and/or (tV) below:

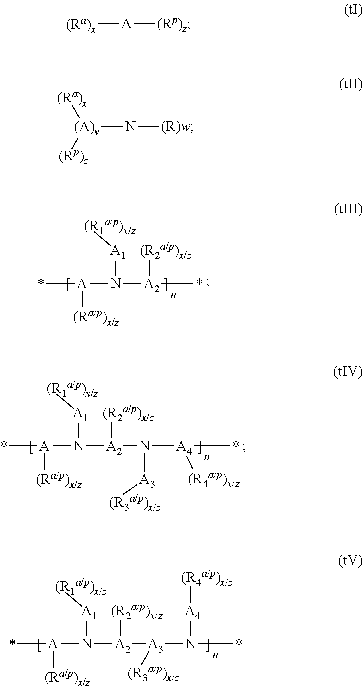

in which N, if present, is a nitrogen atom;
n, if applicable, is in the range of 1-20;
A is a mono-, or polycyclic system comprising at least one pair of a conjugated double bond (—C═C—C═C—), the cyclic system optionally comprising one or several heteroatoms, and optionally being substituted, whereby in a compound comprising several structures A, each A may be selected independently from another A present in the same structure (tII-tV);
each of A₁-A₄, if present, is an A independently selected from the A as defined above;
v in (tII) recites the number of cyclic systems A linked by a single bond to the nitrogen atom and is 1, 2 or 3;
(R)w is an optional residue selected from a hydrocarbon residue comprising from 1 to 30 carbon atoms, optionally substituted and optionally comprising 1 or several heteroatoms, with w being 0, 1 or 2 provided that v+w does not exceed 3, and, if w=2, the respective Rw₁ or Rw₂ being the same or different;
Ra represents a residue capable, optionally together with other Ra present on the same structure (tI-tV), of decreasing the melting point of an organic compound and is selected from a linear, branched or cyclic alkyl or a residue comprising one or several oxygen atoms, wherein the alkyl or the oxygen comprising residue is optionally halogenated;
x is the number of independently selected residues Ra linked to an A and is selected from 0 to a maximum possible number of substituents of a respective A, independently from the number x of other residues Ra linked to another A optionally present;
with the proviso that per structure (tI-tV) there is at least one Ra being an oxygen-containing residue as defined above; and, if several Ra are present on the same structure (I-V), they are the same or different; and wherein two or more Ra may form an oxygen-containing ring;
Rp represents an optional residue enabling a polymerisation reaction with compounds comprising structure (tI-tV) used as monomers, and/or a cross-linking between different compounds comprising structures (tI-tV);
z is the number of residues Rp linked to an A and is 0, 1, and/or 2, independently from the number z of other residues Rp linked to another A optionally present;
Rp may be linked to an N-atom, to an A and/or to a substituent Rp of other structures according (tI-tV), resulting in repeated, cross-linked and/or polymerised moieties of (tI-tV);
(R^{a/p})_{x/z} and (R₁₋₄^{a/p})_{x/z}, if present, represent independently selected residues Ra and Rp as defined above.

Preferably, the charge transporting material comprises compounds having the structures (tI)-(tV).

General reference to the several structures, such as in the references “(tI-tV)”, “(tVII-tXVI)”, or “A₁-A₄”, for example, means reference to any one selected amongst (tI), (tIII), (tIV), or (tV), any one selected amongst (tVII), (tVIII), (tIX), (tX), (tXI), (tXII), (tXIII), (tXIV), (tXV) or (tXVI), or any one selected amongst A₁, A₂, A₃ or A₄, respectively. In addition, in the charge transporting material for use in the invention, for example, different compounds of structures (tI-tV) may be combined and, if desired cross-linked and/or polymerised. Similarly, in any structure (tI-tV), different structures for A may be selected independently, for example from (tVII-tXVI).

According to a preferred embodiment, the organic charge transporting material of the device of the invention comprises a structure according to formula (tVI):

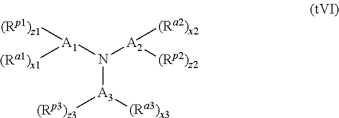

in which Ra1, Ra2 and Ra3 and x1, x2 and x3 are defined, independently, like Ra and x, respectively, above;
Rp1, Rp2 and Rp3 and z1, z2 and z3 are defined, independently, like Rp and z, respectively, above. Formula (tVI) thus represents a specimen of formula (tII) above, in which v is 3, and in which R(w) is absent.

Preferably, A is a mono- or polycyclic, optionally substituted aromatic system, optionally comprising one or several heteroatoms. Preferably, A is mono-, bi- or tricyclic, more preferably mono-, or bicyclic. Preferably, if one or more heteroatoms are present, they are independently selected from O, S, P, and/or N, more preferably from S, P and/or N, most preferably they are N-atoms.

According to a preferred embodiment, A is selected from benzol, naphthalene, indene, fluorene, phenanthrene, anthracene, triphenylene, pyrene, pentalene, perylene, indene, azulene, heptalene, biphenylene, indacene, phenalene, acenaphthene, fluoranthene, and heterocyclic compounds such as pyridine, pyrimidine, pyridazine, quinolizidine, quinoline, isoquinoline, quinoxaline, phthalazine, naphthyridine, quinazoline, cinnoline, pteridine, indolizine, indole, isoindole, carbazole, carboline, acridine, phenanthridine, 1,10-phenanthroline, thiophene, thianthrene, oxanthrene, and derivatives thereof, each of which may optionally be substituted.

According to a preferred embodiment, A is selected from structures of formula (tVII-tXIV) given below:

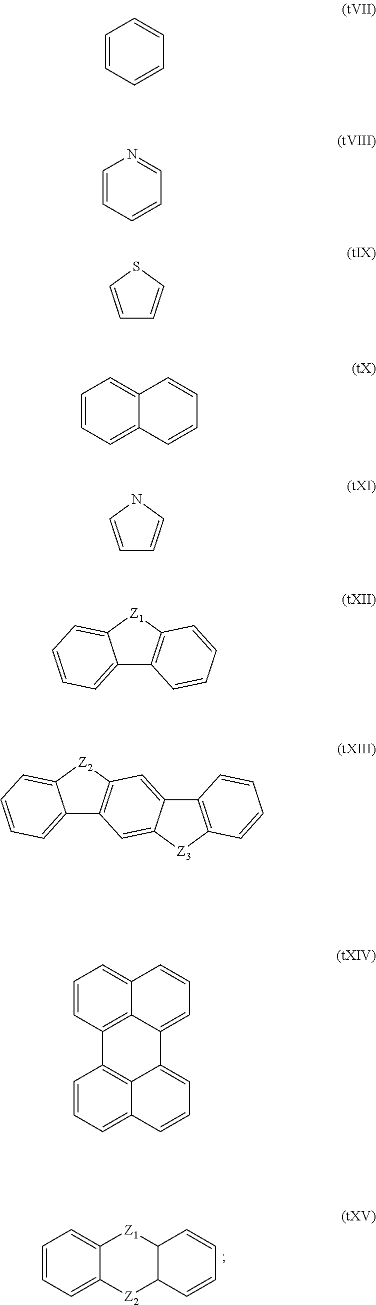

in which each of Z¹, Z² and Z³ is the same or different and is selected from the group consisting of O, S, SO, SO₂, NR¹, N⁺(R^{1′})(^{1″}), C(R²)(R³), Si(R^{2′})(R^{3′}) and P(O)(OR⁴), wherein R¹, R^{1′} and R^{1″} are the same or different and each is selected from the group consisting of hydrogen atoms, alkyl groups, haloalkyl groups, alkoxy groups, alkoxyalkyl groups, aryl groups, aryloxy groups, and aralkyl groups, which are substituted with at least one group of formula —N⁺(R⁵)₃ wherein each group R⁵ is the same or different and is selected from the group consisting of hydrogen atoms, alkyl groups and aryl groups, R², R³, R^{2′} and R^{3′} are the same or different and each is selected from the group consisting of hydrogen atoms, alkyl groups, haloalkyl groups, alkoxy groups, halogen atoms, nitro groups, cyano groups, alkoxyalkyl groups, aryl groups, aryloxy groups and aralkyl groups or R² and R³ together with the carbon atom to which they are attached represent a carbonyl group, and R⁴ is selected from the group consisting of hydrogen atoms, alkyl groups, haloalkyl groups, alkoxyalkyl groups, aryl groups, aryloxy groups and aralkyl groups.

Preferred embodiments of, structure (tXV) for A may be selected from structures (tXVI) and (tXVIa) below:

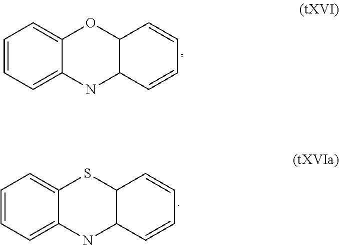

Preferably, in any structure of (tI-tV) all A are the same, but differently substituted. For example, all A are the same, some of which may be substituted and some of which are not. Preferably, all A are the same and identically substituted.

Any A may be substituted by other substituents than Ra and/or Rp. Other substituents may be selected at the choice of the skilled person and no specific requirements are indicated herein with respect to them. Other substituents may thus correspond to (R)w in (tII) defined above. Other substituents and R(w) may generally be selected from linear, branched or cyclic hydrocarbon residues comprising from 1 to 30 carbon atoms, optionally substituted and optionally comprising 1 or several heteroatoms, for example. The hydrocarbon may comprise C—C single, double or triple bonds. For example, it may comprise conjugated double bonds. For example, optional other residues on A may be substituted with halogens, preferably —F and/or —Cl, with —CN or —NO₂, for example.

One or more carbon atoms of other substituents of A may or may not be replaced by any heteroatom and/or group selected from the group of —)—, —C(O)—, —C(O)O—, —S—, —S(O)—, SO₂—, —S(O)₂O—, —N═, —P═, —NR′—, —PR′—, —P(O)(OR′)-, —P(O)(OR′)O—, —P(O)(NR′R′)—, —P(O)(NR′R′)O—, P(O)(NR′R′)NR′—, —S(O)NR′—, and —S(O)₂NR′, with R′ being H, a C₁-C₆ alkyl, optionally partially halogenated.

According to a preferred embodiment, any A may optionally be substituted with one or several substituents independently selected from nitro, cyano, amino groups, and/or substituents selected from alkyl, alkenyl, alkynyl, haloalkyl, alkoxy, and alkoxyalkyl groups, including substituted substituents. Alkyl, alkenyl, alkynyl, haloalkyl, alkoxy and alkoxyalkyl are as defined below.

Preferably, further residues optionally present on A, such as R(w) in (tII), for example, are selected from C₄-C₃₀ alkenes comprising two or more conjugated double bonds.

Ra may be used as a residue capable of controlling the melting point of an organic, charge-transporting compound. The reference with respect to the ability to control the melting point is the same charge transporting material devoid of the at least one residue Ra. In particular, the function of Ra is to provide a charge transporting material that adopts the desired phase at the temperatures indicated herein. The adjustment of the melting point to obtain the desired characteristics in the temperature ranges indicated above may be brought about by a single residue Ra or a combination of identical or different residues Ra, present in any of the structures (tI)-(tV).

At least one linear, branched or cyclic residue containing one or several oxygen atoms may be used for lowering the melting point, and thus the absence of such residues or alternative residues may be used to correspondingly raise melting points, thus obtaining the desired characteristics. Other residues, include for example alkyls as defined below, may assist in the adjustment of the melting point and/or phase characteristics.

Ra may be halogenated and/or perhalogenated in that one, several or all H of the residue Ra may be replaced with halogens. Preferably, the halogen is fluorine.

If Ra is oxygen containing compound, it is preferably a linear, branched, or cyclic saturated C1-C30 hydrocarbon comprising 1-15 oxygen atoms, with the proviso that the number of oxygen atoms does preferably not exceed the number of carbons. Preferably, Ra comprises at least 1.1 to 2 as much carbon as oxygen atoms. Preferably, Ra is a C2-C20, saturated hydrocarbon comprising 2-10 oxygen atoms, more preferably a C3-C10 saturated hydrocarbon comprising 3-6 oxygen atoms.

Preferably, Ra is linear or branched. More preferably Ra is linear.

Preferably, Ra is selected from a C1-C30, preferably C2-C15 and most preferably a C3-C8 alkoxy, alkoxyalkyl, alkoxyalkoxy, alkylalkoxy group as defined below.

Examples of residues Ra may independently be selected from the following structures:

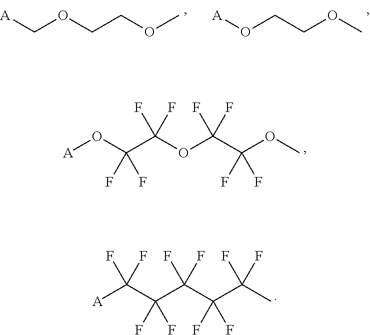

with A indicating any A in formula (tI-V) above.

Any Ra present may be linked to a carbon atom or a heteroatom optionally present in A. If Ra is linked to a heteroatom, it is preferably linked to a N-atom. Preferably, however, any Ra is linked to a carbon atom. Within the same structure (tI-tV), any Ra may be linked to a C or a heteroatom independently of another Ra present on the same A or in the same structure.

Preferably, every structure A, such as A, A₁, A₂, A₃ and A₄, if present in formulae (tI-tV) above comprises at least one residue Ra. For example, in the compound according to structure (tI-tV), at least one structure A comprises an oxygen containing residues Ra as defined above, whereas one or more other and/or the same A of the same compound comprise an aliphatic residue Ra, for example an alkyl group as defined below, preferably a C2-C20, more preferably C3-C15 alkyl, preferably linear.

The following definitions of residues are given with respect to all reference, to the respective residue, in addition to preferred definitions optionally given elsewhere. These apply specifically to the formulae relating to hole transporters (tN formulae) but may optionally also be applied to all other formulae herein where this does not conflict with other definitions provided.

An alkoxyalkoxy group above is an alkoxy group as defined below, which is substituted with one or several alkoxy groups as defined below, whereby any substituting alkoxy groups may be substituted with one or more alkoxy groups, provided that the total number of 30 carbons is not exceeded.

An alkoxy group is a linear, branched or cyclic alkoxy group having from 1 to 30, preferably 2 to 20, more preferably 3-10 carbon atoms.

An alkoxyalkyl group is an alkyl group as defined below substituted with an alkoxy group as defined above.

An alkyl group is a linear, branched and/or cyclic having from 1-30, preferably 2-20, more preferably 3-10, most preferably 4-8 carbon atoms. An alkenyl groups is linear or branched C2-C30, preferably C2-C20, more preferably C3-C10 alkenyl group. An alkynyl group is a linear or branched C2-C30, preferably C2-C20, more preferably C3-C10 linear or branched alkynyl group. In the case that the unsaturated residue, alkenyl or alkynyl has only 2 carbons, it is not branched.

A haloalkyl groups above is an alkyl groups as defined above which is substituted with at least one halogen atom.

An alkylalkoxy group is an alkoxy group as defined above substituted with at least one alkyl group as defined above, provided that the total number of 30 carbons is not exceeded.

The aryl group above and the aryl moiety of the aralkyl groups (which have from 1 to 20 carbon atoms in the alkyl moiety) and the aryloxy groups above is an aromatic hydrocarbon group having from 6 to 14 carbon atoms in one or more rings which may optionally be substituted with at least one substituent selected from the group consisting of nitro groups, cyano groups, amino groups, alkyl groups as defined above, haloalkyl groups as defined above, alkoxyalkyl groups as defined above and alkoxy groups as defined above.

The organic charge transporting material may comprise a residue Rp linked to an A. According to a preferred embodiment, Rp is selected from vinyl, allyl, ethinyl, independently from any other Rp optionally present on the A to which it is linked or optionally present on a different A within the structures (tI) and/or (tII).

The charge transporting material comprised in the device of the invention may be selected from compounds corresponding to the structures of formulae (tI-tV) as such. In this case, n, if applicable, is 1 and the charge transporting material comprises individual compounds of formulae (tI-tV), or mixtures comprising two or more different compounds according formulae (tI-tV).

The compounds of structures (tI-tV) may also be coupled (e.g. dimerised), olilgomerised, polymerized and/or cross-linked. This may, for example, be mediated by the residue Rp optionally present on any of the structures (tI-tV). As a result, oligomers and/or polymers of a given compound selected from (tI-tV) or mixtures of different compounds selected from structures (tI-tV) may be obtained to form a charge transporting material. Small n is preferably in the range of 2-10.

A particularly preferred organic molecular hole transporter contains a Spiro group to retard crystallisation. A most preferred organic hole transporter is a compound of formula tXVII below, and is described in detail in Snaith et al. Applied Physics Letters 89 262114 (2006), which is herein incorporated by reference.

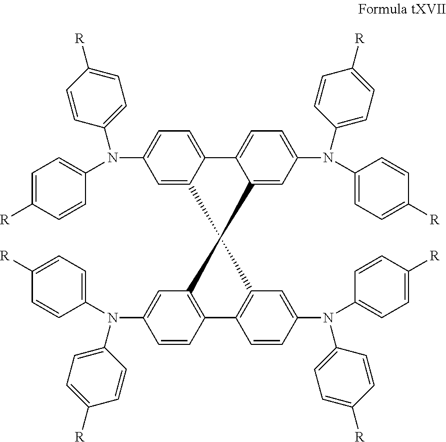

wherein R is alkyl or O-alkyl, where the alkyl group is preferably methyl, ethyl, n-propyl, iso-propyl, n-butyl, sec-butyl or tert-butyl, preferably methyl.

In all aspects, the n-type semiconductor material for use in the solid state DSCs relating to the present invention may be any of those which are well known in the art. Oxides of Ti, Al, Sn, Mg and mixtures thereof are among those suitable. TiO₂ and Al₂O₃ are common examples, as are MgO and SnO₂. The n-type material is used in the form of a layer and will typically be mesoporous, allowing a relatively thick layer of around 0.05-100 μm over which the two or more sensitizers may be absorbed as an intimate mixture at the surface.

In one optional but preferred embodiment, a thin surface coating of a high band-gap/high band gap edge (insulating) material, may be deposited on the surface of a lower band gap semiconductor such as SnO₂. This can greatly reduce this fast recombination from the n-type electrode, which is a much more severe issue in solid state DSCs than in the more widely investigated electrolyte utilising cells.

The n-type material of the solid state heterojunctions relating to all aspects of the present invention is generally a metal compound such as a metal oxide, compound metal oxide, doped metal oxide, selenide, teluride, and/or multicompound semiconductor, any of which may be coated as described above. Suitable materials include single metal oxides such as Al₂O₃, ZrO, ZnO, TiO₂, SnO₂, Ta₂O₅, Nb₂O₅, WO₃, W₂O₅, In₂O₃, Ga₂O₃, Nd₂O₃, Sm₂O₃, La₂O₃, Sc₂O₃, Y₂O₃, NiO, MoO₃, PbO, CdO and/or MnO; compound metal oxides such as ZnₓTi_{y}O_{z}, ZrTiO₄, ZrW₂O₈, SiAlO_{3,5,} Si₂AlO_{5,5,} SiTiO₄ and/or AlTiO₅; doped metal oxides such as any of the single or compound metal oxides indicated above doped with at least one of Al, F, Ge, S, N, In, Mg, Si, C, Pb and/or Sb; carbides such as Cs₂C₅; sulfides such as PbS, CdS, CuS; selenides such as PbSe, CdSe; telurides such as CdTe; nitrides such as TiN; and/or multicompound semiconductors such as CIGaS₂.

It is common practice in the art to generate p-n heterojunctions, especially for optical applications, from a mesoporous layer of the n-type material so that light can interact with the junction at a greater surface than could be provided by a flat junction. In the present case, this mesoporous layer may be conveniently generated by sintering of appropriate semiconductor particles using methods well known in the art and described, for example in Green et al. (J. Phys. Chem. B 109 12525-12533 (2005)) and Kay et al. (Chem. Mater. 17 2930-2835 (2002)), which are both hereby incorporated by reference. With respect to the surface coatings, where present, these may be applied before the particles are sintered into a film, after sintering, or two or more layers may be applied at different stages, as described below.

Typical particle diameters for the semiconductors will be dependent upon the application of the device, but might typically be in the range of 5 to 1000 nm, preferably 10 to 100 nm, more preferably still 10 to 30 nm, such as around 20 nm. Surface areas of 1-1000 m²g⁻¹ are preferable in the finished film, more preferably 30-200 m²g⁻¹, such as 40-100 m²g⁻¹. The film will preferably be electrically continuous (or at least substantially so) in order to allow the injected charge to be conducted out of the device. The thickness of the film will be dependent upon factors such as the photon-capture efficiency of the photo-sensitizer, but may be in the range 0.05-100 μm, such as 0.5-10 μm, preferably 1 to 5 μm. In one alternative embodiment, the film is planar or substantially planar rather than highly porous, and for example has a surface area of 1 to 20 m²g⁻¹ preferably 1 to 10 m²g⁻¹. Such a substantially planar film may also or alternatively have a thickness of 0.05 to 5 μm, preferably 0.1 to 2 μm. In one embodiment, the substantially planar films of the invention are preferably sensitized as described here, with at least one of the sensitizing agents (e.g. the donor, acceptor and/or at least one intermediate sensitizing agent) being a quantum dot sensitizer as described herein.

Where the n-type material is surface coated, materials which are suitable as the coating material (the “surface coating material”) may have a conduction band edge closer to or further from the vacuum level (vacuum energy) than that of the principal n-type semiconductor material, depending upon how the property of the material is to be tuned. They may have a conduction band edge relative to vacuum level of at around −4.8 eV, or higher (less negative) for example −4.8 or −4.7 to −1 eV, such as −4.7 to −2.5 eV, or −4.5 to −3 eV

Suitable coating materials where present include single metal oxides such as MgO, Al₂O₃, ZrO, ZnO, HfO₂, TiO₂, Ta₂O₅, Nb₂O₅, WO₃, W₂O₅, In₂O₃, Ga₂O₃, Nd₂O₃, Sm₂O₃, La₂O₃, Sc₂O₃, Y₂O₃, NiO, MoO₃, PbO, CdO and/or MnO; compound metal oxides such as ZnₓTi_{y}O_{z}, ZrTiO₄, ZrW₂O₈, SiAlO_{3.5}, Si₂AlO_{5.5}, SiTiO₄ and/or AlTiO₅; doped metal oxides such as any of the single or compound metal oxides indicated above doped with at least one of Al, F, Ge, S, N, In, Mg, Si, C, Pb and/or Sb; carbonates such as Cs₂C₅; sulfides such as PbS, CdS, CuS; selenides such as PbSe, CdSe; telurides such as CdTe; nitrides such as TiN; and/or multicompound semiconductors such as CIGaS₂. Some suitable materials are discussed in Grätzel (Nature 414 338-344 (2001)). The most preferred surface coating material is MgO.

Where present, the coating on the n-type material will typically be formed by the deposition of a thin coating of material on the surface of the n-type semiconductor film or the particles which are to generate such a film. In most cases, however, the material will be fired or sintered prior to use, and this may result in the complete or partial integration of the surface coating material into the bulk semiconductor. Thus although the surface coating may be a fully discrete layer at the surface of the semiconductor film, the coating may equally be a surface region in which the semiconductor is merged, integrated, or co-dispersed with the coating material.

Since any coating may not be a fully discrete layer of material, it is difficult to indicate the exact thickness of an appropriate layer. The appropriate thickness will in any case be evident to the skilled worker from routine testing, since a sufficiently thick layer will retard electron-hole recombination without undue loss of charge injection into the n-type material. Coatings from a monolayer to a few nm in thickness are appropriate in most cases (e.g. 0.1 to 100 nm, preferably 1 to 5 nm).

The bulk or “core” of the n-type material in all embodiments of the present invention may be essentially pure semiconductor material, e.g. having only unavoidable impurities, or may alternatively be doped in order to optimise the function of the p-n-heterojunction device, for example by increasing or reducing the conductivity of the n-type semiconductor material or by matching the conduction band in the n-type semiconductor material to the excited state of the chosen sensitizer.

Thus the n-type semiconductor and oxides such as TiO₂, ZnO, SnO₂ and WO₃ referred to herein (where context allows) may be essentially pure semiconductor (e.g. having only unavoidable impurities). Alternatively they may be doped throughout with at least one dopant material of greater valency than the bulk (to provide n-type doping) and/or may be doped with at least one dopant material of lower valency than the bulk (to give p-type doping). n-type doping will tend to increase the n-type character of the semiconductor material while p-type doping will tend to reduce the degree of the natural n-type state (e.g. due to defects).

Such doping may be made with any suitable element including F, Sb, N, Ge, Si, C, In, InO and/or Al. Suitable dopants and doping levels will be evident to those of skill in the art. Doping levels may range from 0.01 to 49% such as 0.5 to 20%, preferably in the range of 5 to 15%. All percentages indicated herein are by weight where context allows, unless indicated otherwise.

The method of the present invention provides for the production of a solid state p-n heterojunction by coating an n-type semiconductor material with a donor sensitizing agent, an acceptor sensitizing agent and optionally at least one intermediate sensitizing agent (all as described herein) and thereafter contacting the sensitized n-type semiconductor material (as described in any of the embodiments herein) with a p-type semiconductor material, particularly one as described herein.

The invention is illustrated further in the following non-limiting examples and in the attached

Figures, in which:

FIG. 1—represents an organic solid state dye sensitised solar cell formed with a mesoporous SnO₂ n-type semiconductor material

FIG. 2a—shows a schematic representation of charge transfers taking place in DSC operation. hν indicates light absorption, e⁻ inj=electron injection, rec=recombination between electrons in the n-type and holes in the p-type material, h⁺inj=hole-transfer (dye regeneration) CB=conduction band.

FIG. 2b—Shows a schematic representation of charge transfers taking place in operation of a co-sensitised DSC. Resonant energy transfer (RET) from the Donor Dye to the Acceptor Dye provides an increase in injected charge over either dye used individually, particularly where the donor Dye is of low injection efficiency (low APCE) and/or where the acceptor dye is of low absorption efficiency or narrow absorption spectrum.

FIG. 2c Shows a schematic representation of charge transfers taking place in operation of a co-sensitised DSC. Resonant energy transfer (RET) from the Donor Dye to the Acceptor Dye via the optional Intermediate Dye provides an increase in injected charge over any dye used individually. Included in this figure is an optional intermediate dye for illustration purposes. Note that hole-transfer to the hole-transporter (h⁺ inj) and electron-transfer to the n-type oxide (e⁻ inj) can take place from any of the dyes, even though it is only illustrated here for the acceptor dye, along side the RET process. We have also included an optional intermediate dye 3 for illustration purposes.

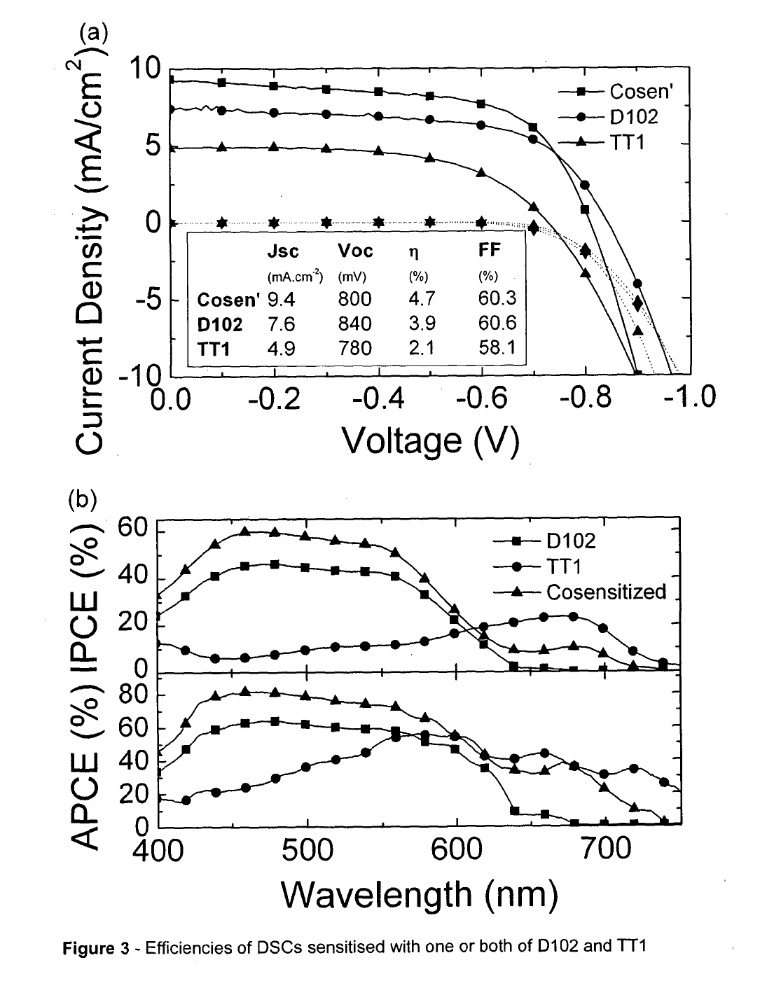

FIG. 3—Shows the efficiencies of DSCs sensitised with one or both of D102 and TT1. 3(a) shows current density-voltage (J-V) characteristics of SDSCs sensitized with D102 (open-triangles), TT1 (closed-squares) and cosensitized with both D102 and TTI (open-circles) and 3(b) shows photovoltaic action spectra for the same cells with Incident Photon-to-electron Conversion Efficiency (IPCE) and Absorbed Photon-to-electron Conversion Efficiency (APCE).

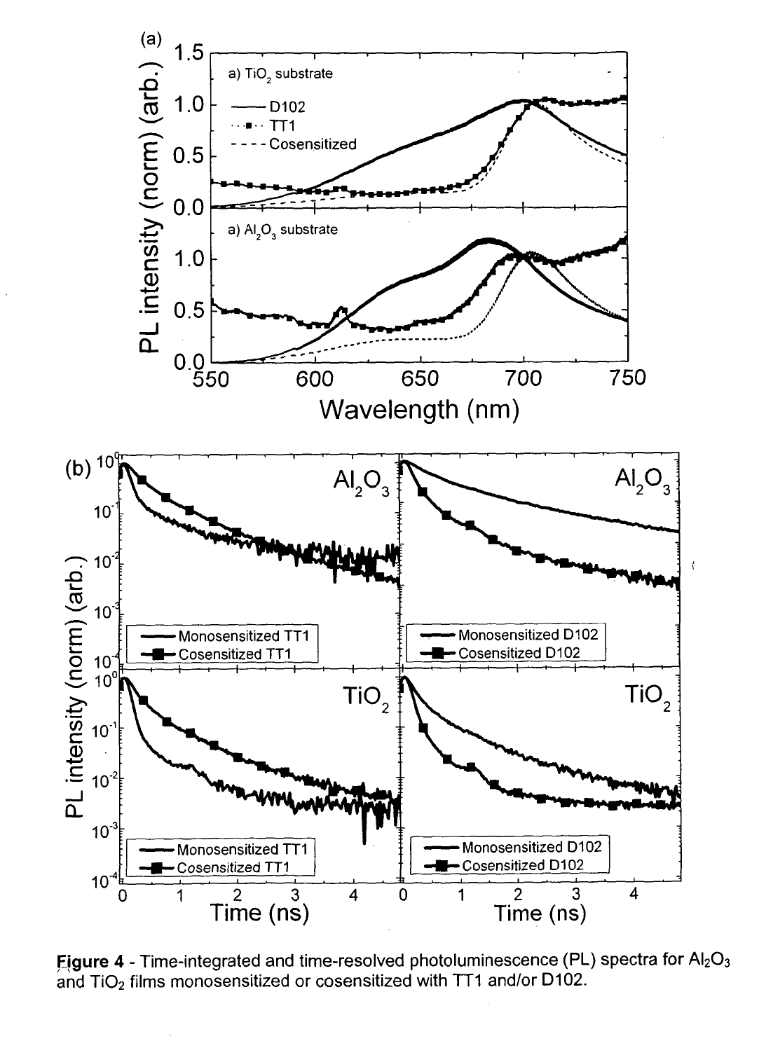

FIG. 4a—Shows the time-integrated photoluminescence (PL) spectrum of individually and cosensitized mesoporous TiO₂ (top) and mesoporous Al₂O₃ (bottom). All spectra are normalized, at 705 nm (top) and at 700 nm (bottom) for ease of comparison.

FIG. 4b—Shows time-resolved PL for the same films. Top row are for sensitized Al₂O₃ and bottom row are for sensitized TiO₂. The left side is probing the emission at 705 nm corresponding to the emission peak from TT1 dye. The right hand side is probing the emission at 650 nm corresponding to predominant emission from D102.

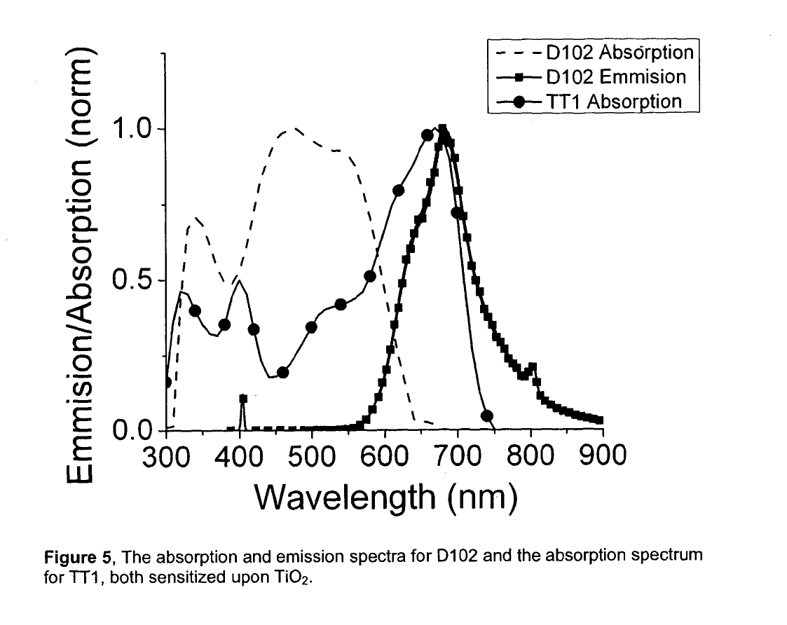

FIG. 5—Shows the absorption and emission spectra for D102 sensitized upon mesoporous TiO₂ and the absorption spectrum for TT1 sensitized upon TiO₂. Note the considerable overlap of the D102 emission and the TTI absorption will facilitate efficient and long range resonant energy transfer.

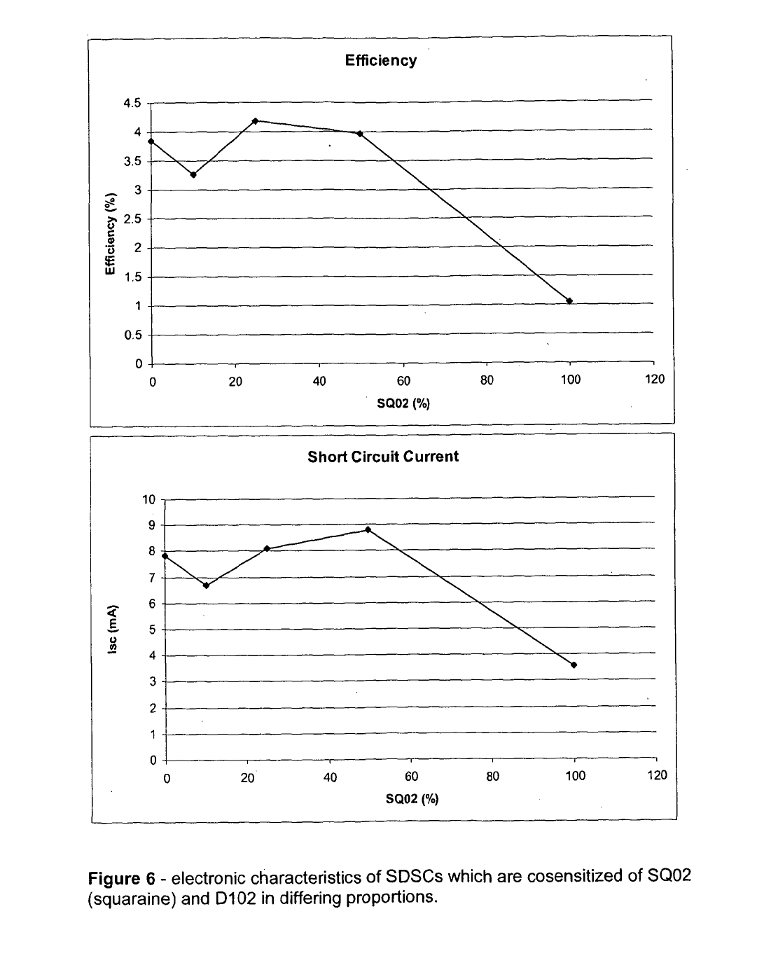

FIG. 6—Shows electronic characteristics SDSCs which are cosensitized with SQ02 (squaraine) and D102 in various proportions.

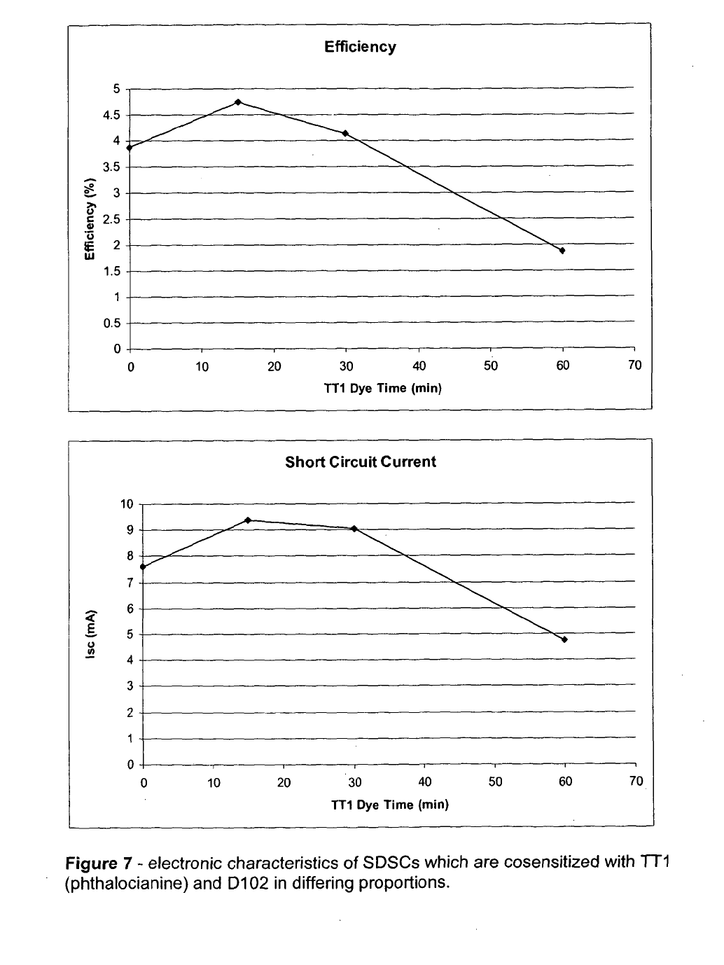

FIG. 7—Shows electronic characteristics SDSCs which are cosensitized with D102 and TT1 in various proportions.

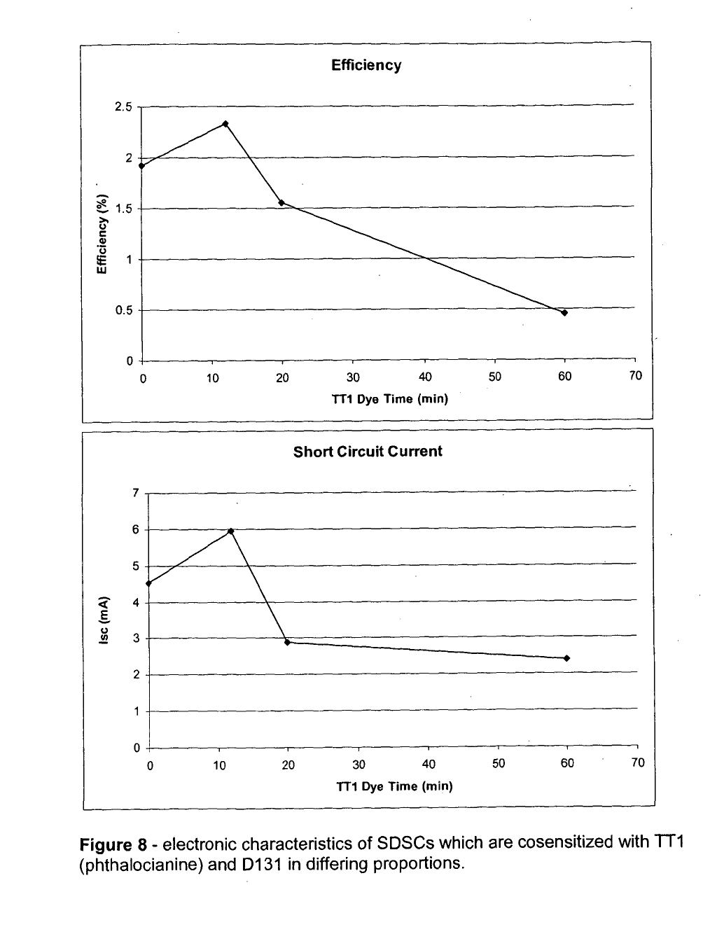

FIG. 8—Shows electronic characteristics SDSCs which are cosensitized with D149 and TT1 in various proportions.

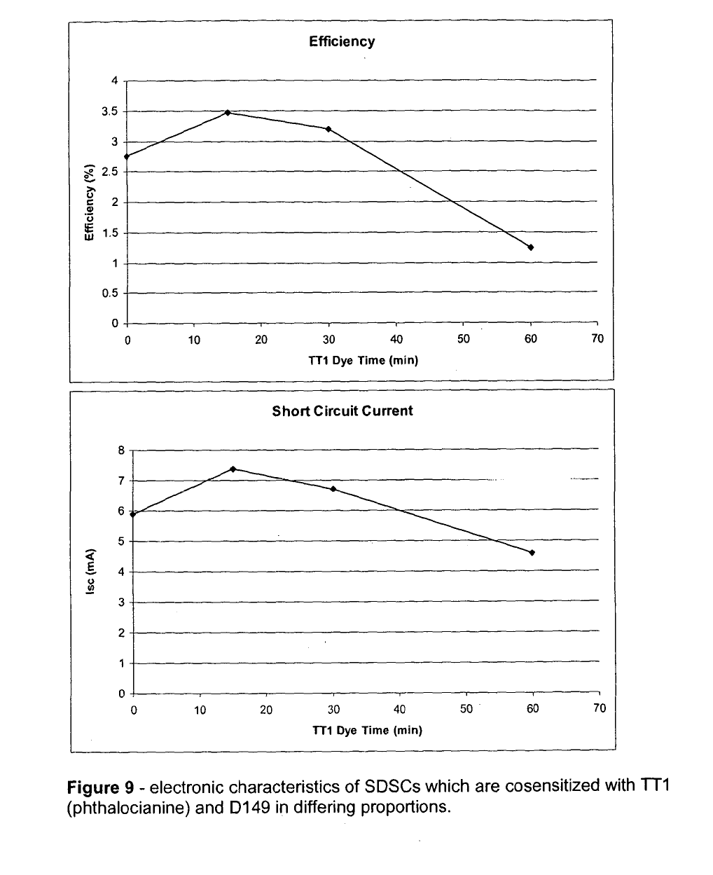

FIG. 9—Shows electronic characteristics SDSCs which are cosensitized with D131 and TT1 in various proportions.

### EXAMPLE 1a

### Solar Cell Fabrication for TiO₂ Based Solar Cells

Cells of the present invention may be fabricated my known methods, including techniques such as described in Kavan, L. and Gratzel, M. Electrochim. Acta 40, 643 (1995) and Snaith, H. J. and Gratzel, M., Adv. Mater. 18, 1910 (2006).

The dye-sensitized solar cells used and presented in these examples were fabricated as follows: Fluorine doped tin oxide (FTO) coated glass sheets (15 Ω/square, Pilkington USA) were etched with zinc powder and HCl (4N) to give the required electrode pattern. The sheets were subsequently cleaned with soap (2% helmanex in water), distilled water, acetone, ethanol and finally treated under oxygen plasma for 10 minutes to remove any organic residues. The FTO sheets were then coated with a compact layer of TiO₂ (100 nm) by aerosol spray pyrolysis deposition at 450° C. using oxygen as the carrier gas and Ti-ACAC dissolved in Ethanol at a 1:10 vol/vol ratio as the precursor (see Gratzel 1995 and Snaith 2006 noted above). A TiO₂ nanoparticle paste purchased from Dyesol (18NR-T) was doctor-bladed onto the compact TiO₂ to give dry film thickness of around 1.4 μm, governed by the height of the doctor blade. These sheets were then slowly heated to 500° C. (ramped over 30 minutes) and baked at this temperature for 30 minutes under an oxygen flow. After cooling, the sheets were cut into slides of the required size and stored in the dark until further use. The final sintered film porosity was 0.6 as determined by nitrogen absorption. Prior to fabrication of each set of devices, the nanoporous films were soaked in a 0.02 M aqueous solution of TiCl₄ at 70 degrees for 1 hr. After rinsing with deionised water and drying in air, the films were baked once more at 500° C. for 45 minutes under oxygen flow with subsequent cooling to 70° C. and placed in a dye solution for the specified times. The hole transporting material used was spiro-OMeTAD, which was dissolved in chlorobenzene at a typical concentration of 180 mg/ml. After fully dissolving the spiro-MeOTAD at 100° C. for 30 minutes the solution was cooled and tertbutyl pyridine (tBP) was added directly to the solution with a volume to mass ratio of 1:26 μl/mg tBP:spiro-OMeTAD. Lithium bis(trifluoromethylsulfonyl)imide salt (Li-TFSI) ionic dopant was pre-dissolved in acetonitrile at 170 mg/ml, then added to the hole-transporter solution at 1:12 μl/mg of Li-TFSI solution:spiro-OMeTAD. The dye coated mesoporous films were briefly rinsed in acetonitrile and dried in air for one minute. A small quantity 20 to 70 μl of the spiro-MeOTAD solution was dispensed onto each dye coated substrate and left for 40 s before spin-coating at 2000 rpm for 25 in air. The films were then placed in a thermal evaporator where 150 nm thick silver electrodes were deposited through a shadow mask under high vacuum (10⁻⁶ mBar). The device area was defined as the overlap between the FTO anode and silvercathode and was approximately 0.12 cm⁻².

### Example 1b

### Solar Cell Fabrication for SnO₂ Based Solar Cells

The SaO₂-based dye-sensitized solar cells of these examples were fabricated as follows: Fluorine doped tin oxide (FTO) coated glass sheets (15 Ω/square, Pilkington USA) were etched with zinc powder and HCl (4N) to give the required electrode pattern. The sheets were subsequently cleaned with soap (2% helmanex in water), distilled water, acetone, ethanol and finally treated under oxygen plasma for 10 minutes to remove any organic residues. The FTO sheets were then coated with a compact layer of SnO₂ (600 nm) by aerosol spray pyrolysis deposition at 450° C. using air as the carrier gas and butly-tinchloride as the precursor, dissolved in ethanol at a 1:10 volume ratio. A homemade SnO₂ nanoparticle paste was doctor-bladed onto the compact SnO₂ to give dry film thickness of around 1.8 μm, governed by the height of the doctor blade. These sheets were then slowly heated to 500° C. (ramped over 30 minutes) and baked at this temperature for 30 minutes under an oxygen flow. After cooling, the sheets were cut into slides of the required size and stored in the dark until further use. The final sintered film porosity was 0.6 as determined by nitrogen absorption. Prior to fabrication of each set of devices, the nanoporous films were soaked in a 0.02 M ethanolic solution of magnesium acetate at 70 degrees for 1 minute. After rinsing with pure ethanol and drying in air, the films were baked once more at 500° C. for 45 minutes with subsequent cooling to 70° C. and placed in a dye solution for the specified times. The hole transporting material used was spiro-OMeTAD, which was dissolved in chlorobenzene at a typical concentration of 180 mg/ml. After fully dissolving the spiro-OMeTAD at 100° C. for 30 minutes the solution was cooled and tertbutyl pyridine (tBP) was added directly to the solution with a volume to mass ratio of 1:26 μl/mg tBP:spiro-OMeTAD. Lithium bis(trifluoromethylsulfonyl)imide salt (Li-TFSI) ionic dopant was pre-dissolved in acetonitrile at 170 mg/ml, then added to the hole-transporter solution at 1:12 μl/mg of Li-TFSI solution:spiro-OMeTAD. The dye coated mesoporous films were briefly rinsed in acetonitrile and dried in air for one minute. A small quantity 20 to 70 μl of the spiro-MeOTAD solution was dispensed onto each dye coated substrate and left for 40 s before spin-coating at 2000 rpm for 25 in air. The films were then placed in a thermal evaporator where 150 nm thick silver electrodes were deposited through a shadow mask under high vacuum (10⁻⁶ mBar). The device area was defined as the overlap between the FTO anode and silver cathode and was approximately 0.12 cm⁻².

### Example 1c

### Dye Sensitization

Once the mesoporous electrodes were re-sintered to 500 degrees for 45 minutes, they were cooled to 70 degrees and then immersed in dye, typically D102 (1 mM in a 1:1 mix of tert-butanol and acetonitrile) and/or TT1 (50 μM TT1+1 mM Chenodeoxycholic acid in a 1:1 mix of tert-butanol and acetonitrile) for varying periods of time and rinsed in ACN before the application of 2,2′,7,7′-tetrakis(N,N-di-p-methoxyphen-amine)-9,9′-spriobifluorene (spiro-OMeTAD) in chlorobenzene by spin-coating. The usual solvent for dyeing is a 1:1 mix of tert-butanol and acetonitrile, however other suitable solvents include, ethanol, chloroform, a mix of ethanol and chloroform, dimethylformamide (DMF), dichloromethane (DCM), toluene and xylene. Dyeing times can vary from 1 minute to 24 hrs, preferably 5 minutes to 1 hr.

### Example 1d

### Modification for Semiconductor Nanoparticle Sensitization

The methods of Example 1a-c may be varied for devices sensitized with PbS nanoparticles: Upon cooling to room temperature the films were taken into a nitrogen filled glove box. A hexane solution of PbS nanoparticles with oleic acid as a ligand had been previously prepared. A second acetonitrile solution of ethylene dithiol (EDT) (20 mM) had also been prepared. The mesoporous films were dipped in the PbS nanoparticle solution and withdrawn to coat with PbS nanoparticles. The films were subsequently dried and dipped in the EDT solution and withdrawn. The EDT acts as to replace the oleic acid ligand, enabling close contact between the SnO₂ based electrode and the PbS. This dipping process was repeated multiply to increase the loading of PbS nanoparticles. After sensitization, the films were dried and the hole-transporter solution was deposited on top, left for 20 seconds and spin-coated at 2000 rpm for 25 seconds. The hole-transporter solution was composed of 180 mg/ml spiro-OMeTAD in chlorobenzene with addition of 17 μl tBP/ml chlorobenzene and 37 μl Li-TFSI solution (170 mg/ml in ACN)/ml chlorobenzene. The solar cells were completed by depositing 150 nm of silver via shadow mask thermal evaporation under high vacuum.

### Example 2

### Solar Cell Testing

Solid-state dye-sensitized solar cells were prepared and characterized as described above. Three cells were prepared, one sensitized with D102 alone, one with TT1 alone and one co-sensitized cell.

D102 sensitization was performed for 1 hr (0.2 mM ACN:tert-Butanol 1:1 solvent mix), and TTI sensitization was performed for 1 hour (50 μM in EtOH+10 mM chenodeoxycholic acid). For cosensitization the films were first sensitized with D102 for 48 minutes followed by TT1 for 12 minutes (the cosensitization times were optimized to maximize SDSC efficiency).

In FIG. 3a is shown the current-voltage curves for the three types of devices, measured under simulated AM1.5 sun light at 100 mWcm⁻². Devices incorporating TTI are observed to have an efficiency of over 2% and a short-circuit current density of 4 mAcm⁻². This in itself is quite high and is approximately double that previously reported for SDSCs incorporating Zn-phthalocyanines. Devices incorporating D102 convert 3.9% of the solar energy to electrical power, with a short-circuit current density of 7.6 mAcm⁻², consistent with previous reports. Cosensitization improves the current density further still, to 9.4 mAcm⁻², with the overall power conversion efficiency improved to 4.7%, which is the highest full sun efficiency observed for an SDSC incorporating an organic sensitizer.

FIG. 3b shows the photovoltaic action spectra for the devices. The IPCE displays an extension into the near IR for the cosensitized cell, as compared to mono D102 sensitization. Unexpectedly, there is also a significant increase in the photo conversion efficiency in the visible region, where D102 already absorbs strongly. To quantify the absorbed photon-to-electron conversion efficiency (APCE) we have estimated the light absorption in the device by measuring the reflectance spectra from silvered devices. Indeed the conversion efficiency is panchromatically enhanced by the presence of the TT1 dye.

In the FIG. 3(a) shows current density-voltage (J-V) characteristics of SDSCs sensitized with D102 (open-triangles), TT1 (closed-squares) and cosensitized with both D102 and TT1 (open-circles) and 3(b) shows photovoltaic action spectra for the same cells as presented in 3a) with incident photon-to-electron conversion efficiency (IPCE) and absorbed photon-to-electron conversion efficiency (APCE).The light absorption in the devices was estimated by measuring the reflectance spectra in an integrating sphere.

### Example 3

### Investigation of RET Charge-Transfer Enhancement

Indolene based dyes (such as D102) are prone to aggregation, and this may render electron-transfer from photo-excited dye less than ideal. If “non-injecting” D102 molecules can transfer their energy to the lower energy dyes prior to exciton decay then this could greatly enhance the performance of these cells. To probe whether surface energy transfer occurs in the system described in Example 2, we performed time-resolved photo-luminescence (PL) measurements on sensitized mesoporous TiO₂ and Al₂O₃. The procedure for the time-correlated single-photon counting (TCSPC) measurements is described in the SI. Films were excited at 400 nm under vacuum. The cells were constructed as described in Example 1, with an equivalent method used for Al₂O₃ based devices

The photoluminescence spectra for D102, TT1 and cosensitized films are shown in FIG. 4a. D102 has a broad visible to near IR emission. On both TiO₂ and Al₂O₃, the visible emission from D102 is almost entirely quenched by cosensitization with TT1. The emission onset for the cosensitized film is almost identical to pure TT1, consistent with highly efficient energy transfer occurring from D102 to TF1. We note that the light absorption in TT1 at 400 nm is very weak and the absolute emission at 700 nm has increased ˜10 fold in the cosensitized films as compared to pure TT1 sensitization. The PL tail observed in pure TTI films is due to reduced sensitivity combined with very low emission signals. The results on both TiO₂ and Al₂O₃ follow the same trend.

The PL decay kinetics are shown in FIG. 4b. On Al₂O₃ the TT1 PL decays faster in the mono-sensitized film than when cosensitized with D102. The D102 emission decays significantly faster in the cosensitized film than in the mono-sensitized film. This is consistent with excitation energy transfer from the D102 feeding the TT1 emission. The PL decays are faster on TiO₂ than on Al₂O₃ consistent with electron transfer to the TiO₂. But once again we observe identical trends to on Al₂O₃. Importantly here, the D102 emission decays significantly faster in the cosensitized films, indicating that D102 excited states contributing to the emission, are much more effectively quenched via energy transfer to TT1 than via electron transfer to TiO₂. This indicates a relatively low injection efficiency from the emissive states directly from D102 in comparison with transfer to the more effectively injecting TT1.

### Example 4

### Alternative Co-Sensitized SDSCs

Equivalent solid-state DSCs to those described in Example 1 were generated with the following pairs of donor and acceptor sensitizers. Each was then tested under varying production conditions to provide the optimum efficiency by combining the two sensitizers at appropriate ratios. The results are show in the indicated figures:

In FIG. 6 is illustrated cells cosensitized with SQ02 (squaraine) and D102. The overall conversion efficiency is shown in part a) and the short circuit current in part b) as a function of the proportion of SQ02 dye. Different dye solutions were made at 0.2 mM in ACN:tert-butanol solvent containing D102 and different concentrations of SQ02. The film dyeing time was kept to 1 hr.

In FIG. 7 is illustrated cells cosensitized with D102 and TT1. D102 is dissolved in ACN:tert-butanol at 0.2 mM concentration and adsorbed for 1 hr. The overall conversion efficiency is shown in part a) and the short circuit current in part b) as a function of the TT1 dye absorption time. TT1 is dissolved in ethanol at 0.07 mM concentration and subsequently adsorbed with varying adsorption times, as indicated in the x-axis.

In FIG. 8 is illustrated cells cosensitized with D149 and TT1. D149 is dissolved in ACN:tert-butanol at 0.07 mM concentration and adsorbed for 1 hr. The overall conversion efficiency is shown in part a) and the short circuit current in part b) as a function of the TT1 dye absorption time. TT1 is dissolved in ethanol at 0.07 mM concentration and subsequently adsorbed with varying adsorption times, as indicated in the x-axis.

In FIG. 9 is illustrated cells cosensitized with D131 and TT1. D131 is dissolved in ACN:tert-butanol at 0.2 mM concentration and adsorbed for 1 hr. The overall conversion efficiency is shown in part a) and the short circuit current in part b) as a function of the TTI dye absorption time. TT1 is dissolved in ethanol at 0.07 mM concentration and subsequently adsorbed with varying adsorption times, as indicated in the x-axis.

### Example 5

### Reflectance Measurement of APCE

UV-vis reflection measurements were performed with a Varian Carry 300 spectrophotometer with an integrating sphere accessory. The integrating sphere was calibrated with a Spectralon standard. Silver metal was evaporated over the entire device substrate (1.96 cm2) after testing, and the silver coated films were placed on the back side of the integrating sphere positioned at an 8° angle to the incident light. The light was incident through the FTO coated glass. All light reflected back out the front of the cell at all angles was collected in the integrating sphere and the total attenuation within the cell estimated. For this measurement we assume all light which is not reflected back into the integrating sphere is absorbed in the photoactive layer. Errors arise from the silver back electrode being only 98% reflective, [Henry J. Snaith, Adam J. Moule, Ce'dric Klein, Klaus Meerholz, Richard H. Friend, and Michael Graltzel, Nano Lett., Vol. 7, No. 11, 2007—incorporated by reference] direct absorption in the FTO-glass and some light escaping out of the side of the system. However, these errors are small, and only become significant when the photoactive layer is weakly absorbing at wavelengths greater than 750 nm.

1. A solid-state p-n heterojunction comprising an organic p-type material in contact with an n-type material wherein said n-type material is surface-sensitised by at least two sensitizing agents comprising a donor sensitizing agent and an acceptor sensitizing agent and optionally at least one intermediate sensitizing agent,
wherein the emission spectrum of the donor sensitizing agent overlaps with the absorption spectrum of the acceptor sensitizing agent and/or with the absorption spectrum of at least one intermediate sensitizing agent, when present,
wherein the emission spectrum of at least one intermediate sensitizing agent, when present, overlaps with the absorption spectrum of the acceptor sensitizing agent, and
wherein the acceptor sensitizing agent individually has a maximum Absorbed Photon to electron Conversion Efficiency of no less than 40% in an equivalent heterojunction when used as the sole sensitizing agent.

2. A solid state p-n heterojunction as claimed in claim 1 wherein said n-type semiconductor material comprises at least one material selected from the group consisting of single metal oxide, compound metal oxide, doped metal oxide, carbonate, sulphide, selenide, teluride, nitrides, multicompound semiconductor, and combinations thereof.

3. A solid-state p-n heterojunction as claimed in claim 1 wherein at least one of said donor, said acceptor and/or any intermediate sensitizing agents are independently selected from the group consisting of an organic dye, a metal-complexed dye, a quantum-dot photosensitizer, and mixtures thereof.

4. A solid-state p-n heterojunction as claimed in claim 3 wherein each of said donor, said acceptor and all intermediate sensitizing agents, if present, are independently an organic dye, a metal-complexed dye or a quantum-dot photosensitizer.

5. A solid state p-n heterojunction as claimed in claim 3 wherein at least one of said organic and metal-complexed dyes is selected from the group consisting of a ruthenium complex dye, a metal-phalocianine complex dye, a metal-porphryin complex dye, a squarine dye, a thiophene based dye, a fluorine based dye, a polymer dye, a quantum dot sensitizer, and mixtures thereof.

6. A solid state p-n heterojunction as claimed in claim 1 wherein the peak absorption wavelength of the donor sensitizing agent is shorter than that of any intermediate sensitizing agents and wherein the peak absorption wavelength of the acceptor sensitizing agent is longer than that of any intermediate sensitizing agents.

7. A solid state p-n heterojunction as claimed in claim 1 wherein the donor sensitizing agent has a maximum Absorbed Photon to electron Conversion Efficiency of less than 40% in an equivalent heterojunction when used as the sole sensitizing agent.

8. A solid state p-n heterojunction as claimed in claim 1 comprising a donor sensitizing agent and an acceptor sensitizing agent wherein the donor and acceptor sensitizing agents correspond to any one of the combinations 2a to 2x as set out in the following table:

| 2-Dye | | |
|---|---|---|
| Combi- | | |
| nation | Donor | Acceptor |
| 2a) | Indoline Dye | Metal-phthalocyanine dye |
| 2b) | Indoline Dye | Squaraine dye (SQ02) |
| 2c) | Indolene Dye | Metal-porphyrin sensitizer |
| 2d) | Indolene Dye | PbS nanoparticles |
| 2e) | Indolene Dye | PbSe nanoparticles |
| 2f) | Metal - ruthenium complex dye | Metal-phthalocyanine dye |
| 2g) | Metal - ruthenium complex dye | Squaraine dye |
| 2h) | Metal - ruthenium complex dye | Metal-porphyrin sensitizer |
| 2i) | Metal - ruthenium complex dye | PbS nanoparticles |
| 2j) | Metal - ruthenium complex dye | PbSe nanoparticles |
| 2k) | Metal-porphyrin complex sensitizer | Metal-phthalocyanine dye |
| 2l) | Metal-porphyrin complex sensitizer | Squaraine dye |
| 2m) | Metal-porphyrin complex sensitizer | PbS nanoparticles |
| 2n) | Metal-porphyrin complex sensitizer | PbSe nanoparticles |
| 2o) | Polyfluorene polymer dye | Metal-phthalocyanine dye |
| 2p) | Polyfluorene polymer dye | Squaraine dye |
| 2q) | Polyfluorene polymer dye | Metal-porphyrin sensitizer |
| 2r) | Polyfluorene polymer dye | PbS nanoparticles |
| 2s) | Polyfluorene polymer dye | PbSe nanoparticles |
| 2t) | Polythiophene polymer | Metal-phthalocyanine dye |
| 2u) | Polythiophene polymer | Squaraine dye |
| 2v) | Polythiophene polymer | Metal-porphyrin sensitizer |
| 2w) | Polythiophene polymer | PbS nanoparticles |
| 2x) | Polythiophene polymer | PbSe nanoparticles |

9. A solid state p-n heterojunction as claimed in claim 1 comprising a donor sensitizing agent, at least one intermediate sensitizing agent and an acceptor sensitizing agent wherein the donor, a first intermediate and the acceptor sensitizing agent correspond to any one of the combinations 3a to 3n as set out in the following table:

| 3-Dye | | | |
|---|---|---|---|
| Combi- | | | |
| nation | Donor | Intermediate | Acceptor |
| 3a) | D131 | D102 | TT1 |
| 3b) | Indolene | Indolene | Indolene |
| 3c) | Indolene | Indolene | Metal-phthalocyanine |
| 3d) | Indolene | Indolene | Squaraine dye |
| 3e) | Indolene | Indolene | Metal-Porphyrin |
| 3f) | Indolene | Indolene | PbS/PbSe |
| 3g) | Indolene | Ru-complex | PbS/PbSe |
| 3h) | Indolene | Metal-Porphyrin | PbS/PbSe |
| 3i) | Indolene | Squaraine | Metal-phthalocyanine |
| 3j) | Indolene | Metal-phthalocyanine | PbS/PbSe |
| 3k) | Indolene | Squaraine | PbS/PbSe |
| 3l) | Ru-Complex | Metal-phthalocyanine | PbS/PbSe |
| 3m) | Ru-Complex | Squaraine | PbS/PbSe |
| 3n) | Metal-Porphyrin | Squaraine | PbS/PbSe |

10. A solid state p-n heterojunction as claimed in claim 1 wherein said p-type material is an organic hole-transporter.

11. A solid state p-n heterojunction as claimed in claim 10 wherein said organic hole-transporter comprises at least one optionally olilgomerised, polymerized and/or cross-linked compound of formula (tI), (tII), (tIII), (tIV) and/or (tV) below, 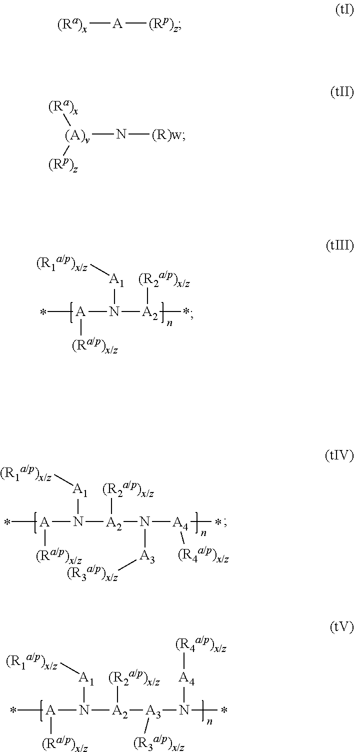
in which N, if present, is a nitrogen atom;
n, if applicable, is in the range of 1-20;
A is a mono-, or polycyclic system comprising at least one pair of a conjugated double bond (—C═C—C═C—), the cyclic system optionally comprising one or more heteroatoms, and optionally being substituted, whereby in a compound comprising more than one structures A, each A may be selected independently from another A present in the same structure (tI-tV);
each of A₁-A₄, if present, is an A independently selected from A as defined above;
v in (tII) recites the number of cyclic systems A linked by a single bond to the nitrogen atom and is 1, 2 or 3;
(R)w is an optional hydrocarbon residue comprising from 1 to 30 carbon atoms, optionally substituted and optionally comprising 1 or more heteroatoms, with w being 0, 1 or 2 provided that v+w does not exceed 3, and, if w=2, the respective Rw₁ or Rw₂ being the same or different;
R^{a} represents a residue capable, optionally together with other R^{a} present on the same structure (tI-tV), of decreasing the melting point of an organic compound and is a linear, branched or cyclic alkyl or a residue comprising one or more oxygen atoms, wherein the alkyl and/or the oxygen comprising residue is optionally halogenated;
x is the number of independently selected residues R^{a} linked to an A and is selected from 0 to a maximum possible number of substituents of a respective A, independently from the number x of other residues R^{a} linked to another A optionally present;
with the proviso that per structure (tI-tV) there is at least one R^{a} being an oxygen containing residue as defined above; and, if more than one R^{a} are present on the same structure (tI-tV), they are the same or different; and wherein two or more R^{a} may form an oxygen-containing ring;
R^{p} represents an optional residue enabling a polymerization reaction with compounds comprising structure (tI-tV) used as monomers, and/or a cross-linking reaction between different compounds comprising structures (tI-tV);
z is the number of residues R^{p} linked to an A and is 0, 1, and/or 2, independently from the number z of other residues R^{p} linked to another A optionally present;
R^{p} may be linked to an N-atom, to an A and/or to a substituent R^{p} of other structures according (tI-tV), resulting in repeated, cross-linked and/or polymerised moieties of (tI-tV); and
(R^{a/p})_{x/y} and (R₁₋₄^{a/p})_{x/z}, if present, represent independently residues R^{a} and R^{p} as defined above.

12. A solid state p-n heterojunction as claimed in claim 10 wherein said organic hole-transporter is a compound of formula tXVII below: 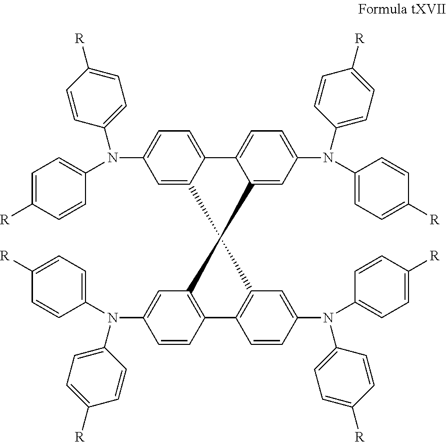
wherein R is C₁-C₆ alkyl or C₁-C₆ O-alkyl.

13. A solid state p-n heterojunction as claimed in claim 1 wherein said n-type material is porous.

14. A solid-state p-n heterojunction as claimed in claim 1 wherein said n-type material is substantially planar and said heterojunction forms a substantially planar junction.

15. A solid-state p-n heterojunction as claimed in claim 1 wherein said n-type material is selected from the group consisting of oxides of Ti, Zn, Sn, W and mixtures thereof, and wherein said n-type material is optionally surface coated.

16. A solid state p-n heterojunction as claimed in claim 1 wherein said n-type semiconductor material is essentially pure material or is doped throughout with at least one dopant material of greater valency than the bulk material (n-type doping) and/or is doped with at least one dopant material of lower valency than the bulk (p-type doping), and in wherein said n-type material is optionally surface coated.

17. A solid-state p-n heterojunction as claimed in claim 1 further comprising an organic p-type material in contact with an n-type material wherein said n-type material is surface-sensitized by two sensitizing agents comprising a donor sensitizing agent and an acceptor sensitizing agent,
wherein the emission spectrum of the donor sensitizing agent overlaps with the absorption spectrum of the acceptor sensitizing agent, and
wherein the acceptor sensitizing agent individually has a maximum Absorbed Photon to electron Conversion Efficiency of no less than 40% in an equivalent heterojunction when used as the sole sensitizing agent.

18. A solid-state p-n heterojunction as claimed in claim 1 further comprising an organic p-type material in contact with an n-type material wherein said n-type material is surface-sensitized by at least three sensitizing agents comprising a donor sensitizing agent, an acceptor sensitizing agent and at least one intermediate sensitizing agent,
wherein the emission spectrum of the donor sensitizing agent overlaps with the absorption spectrum of the acceptor sensitizing agent and/or with the absorption spectrum of at least one intermediate sensitizing agent,
wherein the emission spectrum of at least one intermediate sensitizing agent overlaps with the absorption spectrum of the acceptor sensitizing agent, and
wherein the acceptor sensitizing agent individually has a maximum Absorbed Photon to electron Conversion Efficiency of no less than 40% in an equivalent heterojunction when used as sole sensitizing agent.

19. An optoelectronic device comprising at least one solid state p-n heterojunction as claimed in claim 1.

20. An optoelectronic device as claimed in claim 19 wherein said device is a solar cell or photo-detector.

21. An optoelectronic device as claimed in claim 19 wherein said device is a solar cell.

22. A method of using at least two sensitizing agents in a solid-state p-n heterojunction, said sensitizing agents comprising a donor sensitizing agent and an acceptor sensitizing agent and optionally at least one intermediate sensitizing agent,
wherein the emission spectrum of the donor sensitizing agent overlaps with the absorption spectrum of the acceptor sensitizing agent and/or with the absorption spectrum of at least one intermediate sensitizing agent, when present,
wherein the emission spectrum of at least one intermediate sensitizing agent, when present, overlaps with the absorption spectrum of the acceptor sensitizing agent; and
wherein the acceptor sensitizing agent individually has a maximum Absorbed Photon to electron Conversion Efficiency of no less than 40% in an equivalent heterojunction when used as the sole sensitizing agent.

23. The method as claimed in claim 22 wherein said heterojunction is an organic solid state p-n heterojunction as claimed in claim 1.

24. The method as claimed in claim 22, wherein said sensitizing agents generate increased charge transfer in the solid-state p-n heterojunction in comparison with any of the individual sensitizing agents used as the sole sensitizer in an equivalent heterojunction.

25. The method as claimed in claim 24 wherein said increased charge transfer occurs at least partially by resonant energy transfer between the donor sensitizer and the acceptor sensitizer, between the donor sensitizer and at least one intermediate sensitizer, when present, and/or between at least one intermediate sensitizer, when present, and the acceptor sensitizer.

26. The method as claimed in claim 22 wherein said solid-state p-n heterojunction is in a solar cell.

27. A method of preparing a solid-state p-n heterojunction comprising:
forming a layer of an n-type semiconductor material; and
surface sensitizing said layer simultaneously or sequentially with at least two sensitizing agents comprising a donor sensitizing agent and an acceptor sensitizing agent and optionally at least one intermediate sensitizing agent,
wherein the emission spectrum of the donor sensitizing agent overlaps with the absorption spectrum of the acceptor sensitizing agent and/or with the absorption spectrum of at least one intermediate sensitizing agent, when present, and
wherein the emission spectrum of at least one intermediate sensitizing agent, when present, overlaps with the absorption spectrum of the acceptor sensitizing agent.

28. An optoelectronic device comprising at least one solid-state p-n heterojunction formed or formable by the method of claim 27.

29. The solid-state p-n heterojunction of claim 2, wherein said n-type semiconductor material is TiO₂.

30. The solid state p-n heterojunction of claim 10, wherein said p-type material is a substantially amorphous organic hole transporter.

31. The solid state p-n heterojunction of claim 13, wherein said n-type material has a surface area of 1-1000 m²g⁻¹.

32. The solid state p-n heterojunction of claim 13, wherein said n-type material is in the form of an electrically continuous layer.

33. The solid state p-n heterojunction of claim 32, wherein said electrically continuous layer has a thickness of 0.5 to 20 μm.

34. The method of claim 27, wherein said layer of the n-type semiconductor material is a porous layer.

35. The optoelectronic device of claim 28, wherein said optoelectronic device is a photovoltaic cell or a light sensing device.
